(19) United States
(12) Patent Application Publication
(10) Pub. No.: US 2025/0271660 A1
(43) Pub. Date: Aug. 28, 2025

(54) MOVABLE DEVICE, IMAGE PROJECTION APPARATUS, HEAD-UP DISPLAY, LASER HEADLAMP, HEAD-MOUNTED DISPLAY, OBJECT RECOGNITION APPARATUS, AND MOVING BODY

(71) Applicant: Goichi AKANUMA, Kanagawa (JP)

(72) Inventor: Goichi AKANUMA, Kanagawa (JP)

(21) Appl. No.: 19/056,801

(22) Filed: Feb. 19, 2025

(30) Foreign Application Priority Data
Feb. 27, 2024 (JP) 2024-027665

(51) Int. Cl. G02B 26/10; F21S 41/675; G02B 26/08

(52) U.S. Cl. CPC G02B 26/101; G02B 26/0833; F21S 41/675

(57) ABSTRACT

A movable device includes a fixed frame, a movable portion, multiple drive beams to drive the movable portion. Each of the multiple drive beams has an end directly or indirectly coupled to the movable portion and another end coupled to the fixed frame. Each of the multiple drive beams includes: an upper drive beam and a lower drive beam separated from the upper drive beam in a normal direction of the fixed frame.

### CROSS-REFERENCE TO RELATED APPLICATIONS

This patent application is based on and claims priority pursuant to 35 U.S.C. § 119(a) to Japanese Patent Application No. 2024-027665, filed on Feb. 27, 2024, in the Japan Patent Office, the entire disclosure of which is hereby incorporated by reference herein.

### BACKGROUND

### Technical Field

The present disclosure relates to a movable device, an image projection apparatus, a head-up display, a laser headlamp, a head-mounted display, an object recognition apparatus, and a moving body.

### Related Art

A movable device such as a micro electro mechanical systems (MEMS) device manufactured by micromachining silicon or glass is known.

For example, in the related art, a displacement control actuator has been proposed that includes a piezoelectric element in which first main surfaces of at least two piezoelectric substrates having first and second main surfaces are bonded to each other by using direct bonding in order to obtain a large displacement amount.

However, in a movable device such as the displacement control actuator proposed in the related art, the rigidity of the deformable part is reduced in order to obtain a large displacement amount. The operation stability is lowered due to the reduced rigidity of the deformable part, and accordingly there is room for increasing the operation stability.

### SUMMARY

According to an embodiment of the present disclosure, a movable device includes a fixed frame, a movable portion, and multiple drive beams to drive the movable portion. Each of the multiple drive beams has an end directly or indirectly coupled to the movable portion and another end coupled to the fixed frame. Each of the multiple drive beams includes an upper drive beam and a lower drive beam separated from the upper drive beam in a normal direction of the fixed frame.

According to an embodiment of the present disclosure, an image projection apparatus includes the movable device.

According to an embodiment of the present disclosure, a head-up display includes the movable device.

According to an embodiment of the present disclosure, a laser headlamp includes the movable device.

According to an embodiment of the present disclosure, a head-mounted display includes the movable device.

According to an embodiment of the present disclosure, an object recognition apparatus includes the movable device.

According to an embodiment of the present disclosure, a moving body includes the head-up display.

According to an embodiment of the present disclosure, a moving body includes the laser headlamp.

According to an embodiment of the present disclosure, a moving body includes the object recognition apparatus.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a schematic top view of a movable device according to a first embodiment of the present disclosure;

FIG. 2 is a schematic cross-sectional view of the movable device taken along the line II-II in FIG. 1;

FIG. 3 is a schematic cross-sectional view of the movable device taken along the line III-III in FIG. 1;

FIG. 4 is a schematic bottom view of the movable device according to the first embodiment of the present disclosure;

FIG. 5 is a schematic cross-sectional view of the movable device taken along the line V-V in FIG. 1;

FIG. 6 is a first schematic perspective view of a movable portion oscillated by a second upper drive portion in the movable device according to the first embodiment of the present disclosure;

FIG. 7 is a second schematic perspective view of the movable portion oscillated by the second upper drive portion in the movable device according to the first embodiment of the present disclosure;

FIG. 8 is a third schematic perspective view of the movable portion oscillated by the second upper drive portion in the movable device according to the first embodiment of the present disclosure;

FIG. 9 is a fourth schematic perspective view of the movable portion oscillated by the second upper drive portion in the movable device according to the first embodiment of the present disclosure;

FIG. 10 is a first diagram illustrating a waveform of a drive voltage applied to a drive portion group of the movable device according to the first embodiment of the present disclosure;

FIG. 11 is a second diagram illustrating a waveform of a drive voltage applied to a drive portion group of the movable device according to the first embodiment of the present disclosure;

FIG. 12 is a diagram illustrating a waveform the waveform of the drive voltage in FIG. 10 and the waveform of the drive voltage in FIG. 11 are superimposed;

FIG. 13 is a schematic top view of a movable device according to a second embodiment of the present disclosure;

FIG. 14 is a schematic cross-sectional view of the movable device taken along the line XIV-XIV in FIG. 13;

FIG. 15 is a schematic cross-sectional view of the movable device taken along the line XV-XV in FIG. 13;

FIG. 16 is a schematic bottom view of the movable device according to the second embodiment of the present disclosure;

FIG. 17 is a schematic cross-sectional view of the movable device taken along the line XVII-XVII in FIG. 13;

FIG. 18 is a schematic top view of a movable device according to a third embodiment of the present disclosure;

FIG. 19 is a schematic top view of the movable device taken along the line XIV-XIV in FIG. 20;

FIG. 20 is a schematic cross-sectional view of the movable device taken along the line XX-XX in FIG. 18;

FIG. 21 is a schematic cross-sectional view of the movable device taken along the line XXI-XXI in FIG. 18;

FIG. 22 is a schematic bottom view of the movable device according to the third embodiment of the present disclosure;

FIG. 23 is a schematic cross-sectional view of the movable device taken along the line XXIII-XXIII in FIG. 18;

FIG. 24 is a schematic top view of a movable device according to a fourth embodiment of the present disclosure;

FIG. 25 is a schematic cross-sectional view of the movable device taken along the line XXV-XXV in FIG. 24;

FIG. 26 is a schematic cross-sectional view of the movable device taken along the line XXVI-XXVI in FIG. 24;

FIG. 27 is a schematic bottom view of the movable device according to the fourth embodiment of the present disclosure;

FIG. 28 is a schematic cross-sectional view of the movable device taken along the line XXVIII-XXVIII in FIG. 24;

FIG. 29 is a schematic top view of a movable device according to a fifth embodiment of the present disclosure;

FIG. 30 is a schematic cross-sectional view of the movable device taken along the line XXX-XXX in FIG. 29;

FIG. 31 is a schematic cross-sectional view of the movable device taken along the line XXXI-XXXI in FIG. 29;

FIG. 32 is a schematic bottom view of the movable device according to the fifth embodiment of the present disclosure;

FIG. 33 is a schematic cross-sectional view of the movable device taken along the line XXXIII-XXXIII in FIG. 29;

FIG. 34 is a schematic top view of a movable device according to a sixth embodiment of the present disclosure;

FIG. 35 is a schematic cross-sectional view of the movable device taken along the line XXXV-XXXV in FIG. 34;

FIG. 36 is a schematic cross-sectional view of the movable device taken along the line XXXVI-XXXVI in FIG. 34;

FIG. 37 is a schematic bottom view of the movable device according to the sixth embodiment of the present disclosure;

FIG. 38 is a schematic cross-sectional view of the movable device taken along the line XXXVIII-XXXVIII in FIG. 34;

FIG. 39 is a schematic diagram illustrating an example of a light scan system;

FIG. 40 is a diagram illustrating a hardware configuration of a light scan system;

FIG. 41 is a functional block diagram illustrating an example of a control device;

FIG. 42 is a flowchart of an example of a process related to a light scan system;

FIG. 43 is a schematic diagram illustrating an example of an automobile including a head-up display apparatus;

FIG. 44 is a schematic diagram illustrating an example of a head-up display apparatus;

FIG. 45 is a schematic diagram illustrating an example of an image forming apparatus including an optical writing device;

FIG. 46 is a schematic diagram illustrating an example of an optical writing device;

FIG. 47 is a schematic diagram illustrating an example of an automobile including a laser imaging detection and ranging apparatus;

FIG. 48 is a schematic diagram illustrating an example of a laser imaging detection and ranging apparatus;

FIG. 49 is a schematic diagram illustrating an example of a configuration of a laser headlamp;

FIG. 50 is a schematic perspective view of an example of a configuration of a head-mounted display.

FIG. 51 is a schematic diagram illustrating an example of a portion of a configuration of a head-mounted display;

FIG. 52 is a first schematic diagram illustrating an example of a pupil-or-cornea position detection apparatus; and

FIG. 53 is a second schematic diagram illustrating an example of a pupil-or-cornea position detection apparatus.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

According to an embodiment of the present disclosure, a movable device that can obtain a large displacement amount while increasing a displacement stability can be provided.

A movable device, an image projection apparatus, a head-up display, a laser headlamp, a head-mounted display, an object recognition apparatus, and a moving body according to embodiments of the present disclosure will be described in detail with reference to the drawings. However, the following embodiments are intended to describe the movable device, the image projection apparatus, the head-up display, the laser headlamp, the head-mounted display, the object recognition apparatus, and the moving body according to some embodiments of the present disclosure, and the scope of the present disclosure is not limited to the following embodiments.

The dimensions, materials, shapes, and relative positions of the components described in embodiments of the present disclosure are not intended to limit the scope of the embodiments of the present disclosure to only those of the components, and are merely examples of explanation, unless otherwise specified. The relative positions or the size of the elements illustrated in the drawings may be exaggerated for purpose of clear description. In the following description, common or corresponding elements are denoted by the same or similar reference signs, and redundant description is appropriately simplified or omitted.

In the following, the arrangement and configuration of the respective parts will be described using an XYZ orthogonal coordinate system for the sake of easy understanding of the description. The three axes in the XYZ orthogonal coordinate system are orthogonal to each other. In the XYZ orthogonal coordinate system, a direction in which the X-axis extends is referred to as an “X-direction”, a direction in which the Y-axis extends is referred to as a “Y-direction”, and a direction in which the Z-axis extends is referred to as a “Z-direction”. The direction in which the arrow indicating the X-axis is directed is referred to as +X-direction, and the direction opposite to the +X-direction is referred to as −X-direction. The direction in which the arrow indicating the Y-axis is directed is referred to as +Y-direction, and the direction opposite to the +Y-direction is referred to as −Y-direction. The direction in which the arrow indicating the Z-axis is directed is referred to as +Z-direction, and the direction opposite to the +Z-direction is referred to as −Z-direction.

In embodiments of the present disclosure, the +Z-direction is referred to as “upper” and the −Z-direction is referred to as “lower”. Viewing an object from the +Z-direction is referred to as top view. However, these directional representations merely describe the relation of relative positions, orientations, and directions, and may not be consistent with the relation in use. These directions are independent of the direction of gravity. For example, in an embodiment of the present disclosure, an upper drive portion may not be disposed on the upper side in the gravity direction, but may be disposed on the relatively opposite side to a lower drive portion.

The term “disposed” is not only limited to the case of direct contact, but also includes the case of indirect disposition, for example, with another member interposed. In the present specification, the term “orthogonal” may include an error within the range of ±10° with respect to 90°. Further, in the present specification, the term “parallel” may include an error within the range of ±10° with respect to 0°.

### First Embodiment

### Structure of Movable Device According to First Embodiment

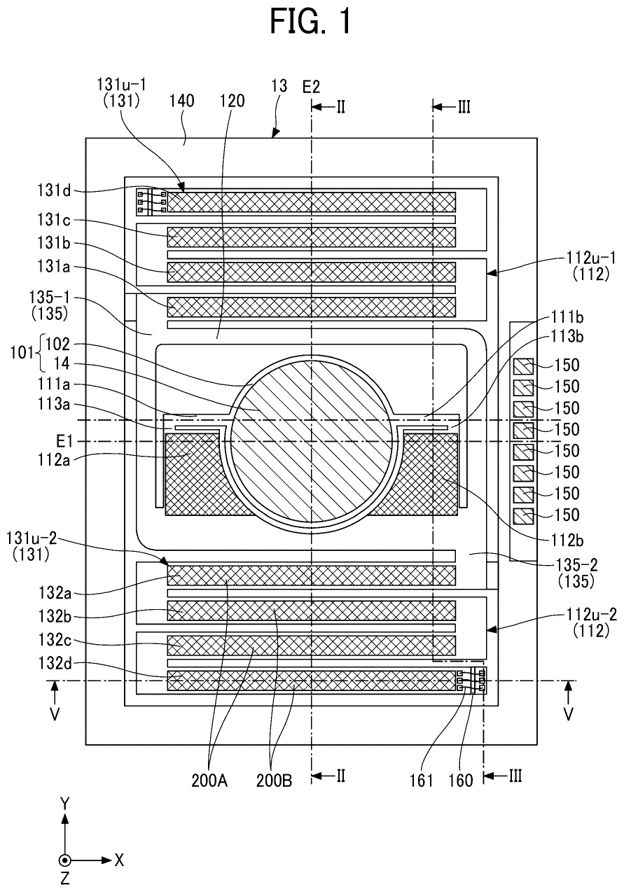

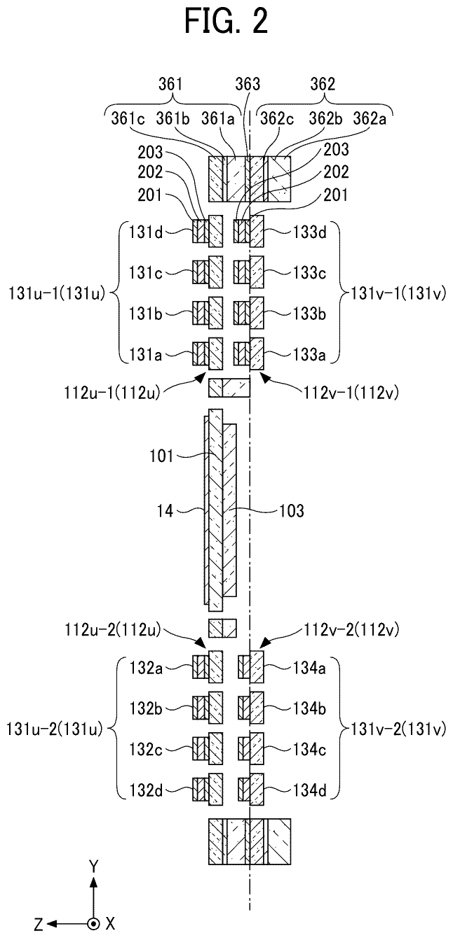

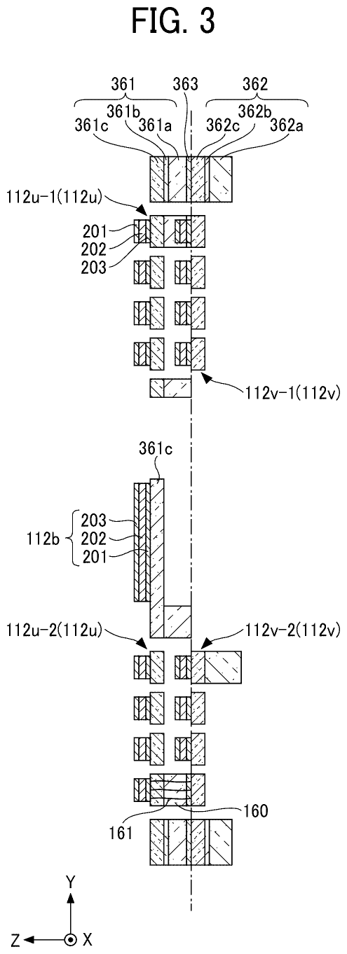

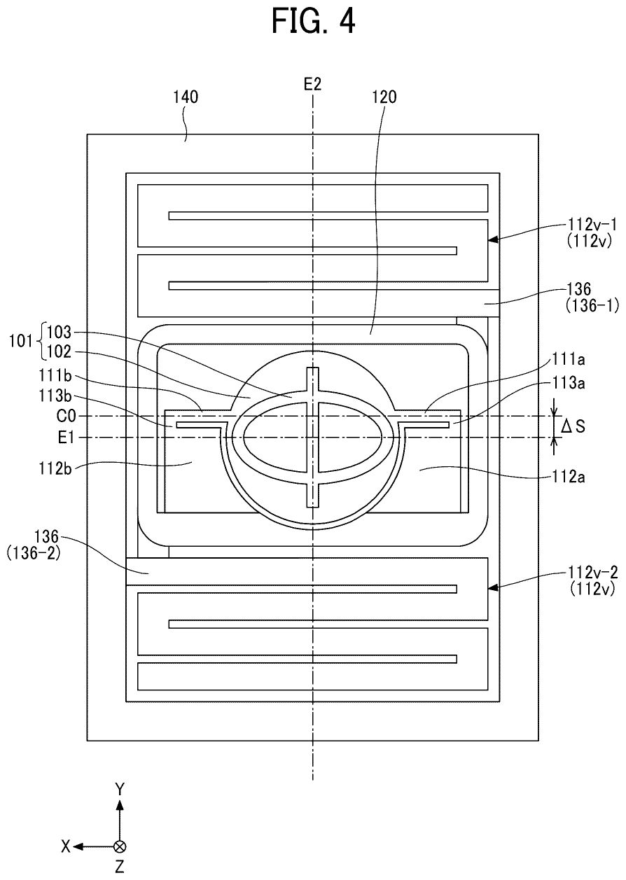

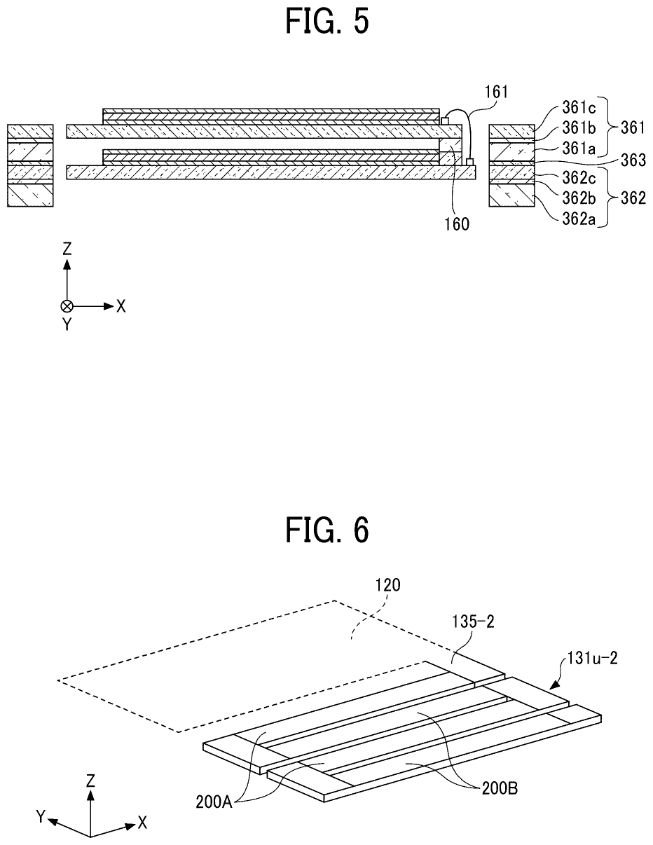

A movable device according to a first embodiment of the present disclosure will be described with reference to FIGS. 1 to 5. FIG. 1 is a schematic top view of an example of the movable device 13 according to the first embodiment of the present disclosure. FIG. 2 is a schematic cross-sectional view of the movable device 13 taken along the line II-II in FIG. 1. FIG. 3 is a schematic cross-sectional view of the movable device 13 taken along the line III-III in FIG. 1. FIG. 4 is a schematic bottom view of an example of the movable device 13 according to the first embodiment of the present disclosure. FIG. 5 is a schematic cross-sectional view of the movable device 13 taken along the line V-V in FIG. 1.

The movable device 13 includes a movable portion 101, a drive beam 112, and a fixed frame 140. The drive beam 112 has one end 135 (see FIG. 1) indirectly coupled to the movable portion 101 via a support portion 120 and drives the movable portion 101. The other end 136 (see FIG. 4) of the drive beam 112 coupled to the fixed frame 140. In the example illustrated in FIGS. 1 to 5, the movable device 13 includes a support portion 120 and electrode connecting portions 150.

The drive beam 112 includes multiple drive beams each having a drive portion 131. As illustrated in FIGS. 2 and 3, the drive beam 112 includes multiple upper drive beams 112u and multiple lower drive beams 112v arranged apart from the multiple upper drive beams 112u in the normal direction of the fixed frame 140. Each of the multiple upper drive beams 112u includes a first silicon on insulator (SOI) substrate 361 and an upper drive portion 131u. Each of the multiple lower drive beams 112v includes a second SOI substrate 362 and a lower drive portion 131v.

The normal direction of the fixed frame 140 is a direction parallel to the normal of a virtual plane including the outer edge of the fixed frame 140 in a top view. In another aspect, the normal direction of the fixed frame 140 is a direction orthogonal to the first axis E1 and the second axis E2. In still another aspect, the normal direction of the fixed frame 140 is a direction parallel to the normal of the movable portion 101 in a state where the movable portion 101 is not driven by the drive beam 112. In the examples illustrated in FIGS. 1 to 5, the normal of the fixed frame 140 is along the Z-axis.

In the example illustrated in FIG. 1, the movable portion 101 is driven by the drive beam 112 so that the movable portion is displaced so as to oscillate (rotationally vibrate) about the second axis E2 along the Y-axis as a rotation axis. The drive beam 112 includes a first upper drive beam 112u-1 arranged at one side (+Y-direction) of the movable portion 101 in the direction along the second axis E2, and a second upper drive beam 112u-2 arranged at the other side (−Y-direction) of the movable portion 101. The drive portion 131 includes a first upper drive portion 131u-1 of the first upper drive beam 112u-1 and a second upper drive portion 131u-2 of the second upper drive beam 112u-2. The one end 135 includes a first end 135-1 at which the first upper drive beam 112u-1 is coupled to the movable portion 101, and a second end 135-2 at which the second upper drive beam 112u-2 is coupled to the movable portion 101.

In the example illustrated in FIG. 1, in order to indicate that the drive beam 112 includes the first upper drive beam 112u-1, the reference sign of the first upper drive beam 112u-1 is written together with the reference sign of the drive beam 112 in parentheses. In addition, in order to indicate that the drive beam 112 includes the second upper drive beam 112u-2, the reference sign of the second upper drive beam 112u-2 is written together with the reference sign of the drive beam 112 in parentheses. In addition, in order to indicate that the drive portion 131 includes the first upper drive portion 131u-1, the reference sign of the first upper drive portion 131u-1 is written together with the reference sign of the drive portion 131 in parentheses. In addition, in order to indicate that the drive portion 131 includes the second upper drive portion 131u-2, the reference sign of the second upper drive portion 131u-2 is written together with the reference sign of the drive portion 131 in parentheses. In the following drawings other than FIG. 1, reference signs may be written together for the same purpose.

As illustrated in FIG. 2, the drive beam 112 includes multiple upper drive beams 112u and multiple lower drive beams 112v. The upper drive beam 112u includes a first upper drive beam 112u-1 and a second upper drive beam 112u-2. The lower drive beam 112v includes a first lower drive beam 112v-1 and a second lower drive beam 112v-2. The drive portion 131 includes an upper drive portion 131u disposed at the upper drive beam 112u and a lower drive portion 131v disposed at the lower drive beam 112v. The upper drive portion 131u includes a first upper drive portion 131u-1 disposed at the first upper drive beam 112u-1 and a second upper drive portion 131u-2 disposed at the second upper drive beam 112u-2. The lower drive portion 131v includes a first lower drive portion 131v-1 disposed at the first lower drive beam 112v-1 and a second lower drive portion 131v-2 disposed at the second lower drive beam 112v-2. In the example illustrated in FIG. 4, the other end 136 includes a first other end 136-1 to which the first lower drive beam 112v-1 is coupled to the fixed frame 140, and a second other end 136-2 at which the second lower drive beam 112v-2 is coupled to the fixed frame 140.

In the example illustrated in FIGS. 1 and 2, the first upper drive portion 131u-1 includes a first upper drive portion 131a, a first upper drive portion 131b, a first upper drive portion 131c, and a first upper drive portion 131d. The second upper drive portion 131u-2 includes a second upper drive portion 132a, a second upper drive portion 132b, a second upper drive portion 132c, and a second upper drive portion 132d. In the example illustrated in FIG. 2, the first lower drive portion 131v-1 includes a first lower drive portion 133a, a first lower drive portion 133b, a first lower drive portion 133c, and a first lower drive portion 133d. The second lower drive portion 131v-2 includes a second lower drive portion 134a, a second lower drive portion 134b, a second lower drive portion 134c, and a second lower drive portion 134d.

In the movable device, for example, when a large drive voltage is applied to the drive beam in order to displace the movable portion by a large displacement amount, the drive portion such as the piezoelectric film may not withstand the drive voltage, and the drive beam may be broken. In addition, when the rigidity of the structure supporting the movable portion is reduced in order to displace the movable portion by a large displacement amount, the resonance frequency of the movable device is lowered. Accordingly, the displacement stability of the movable portion may be impaired.

In the movable device 13 according to an embodiment of the present disclosure, the drive beam 112 includes an upper drive beam 112u and a lower drive beam 112v, and displaces the movable portion 101 by a displacement amount obtained by combining the displacement by the upper drive beam 112u and the displacement by the lower drive beam 112v. Accordingly, the movable portion 101 can be displaced by a large displacement amount without applying a large drive voltage to the drive beam 112. Further, since the structure that supports the movable portion 101 is formed so as not to lower the rigidity of the structure, the displacement stability of the movable portion 101 is not impaired. As described above, in the present embodiment, the movable device 13 that can obtain a large displacement amount while increasing the displacement stability can be provided.

In the movable device 13, the upper drive beam 112u overlaps the lower drive beam 112v as viewed from the normal direction of the fixed frame 140. As viewed from the normal direction of the fixed frame 140, the upper drive beam 112u overlaps the lower drive beam 112v. Thus, the area of the movable device 13 in a virtual plane orthogonal to the normal of the fixed frame 140 is reduced, and the movable device 13 can be reduced in size, as compared with the case where the upper drive beam 112u does not overlap the lower drive beam 112v. In the overlap between the upper drive beam 112u and the lower drive beam 112v, at least a portion of the upper drive beam 112u may overlap the lower drive beam 112v as viewed from the normal direction of the fixed frame 140. When substantially the entire upper drive beam 112u overlaps the lower drive beam 112v as viewed from the normal direction of the fixed frame 140, the area of the movable device 13 in the virtual plane orthogonal to the normal of the fixed frame 140 is minimized, and the movable device 13 can be reduced in size to the minimum.

In the movable device 13, the upper drive beam 112u is coupled to the lower drive beam 112v by an adhesive. In the example illustrated in FIG. 5, the upper drive beam 112u is coupled to the lower drive beam 112v by an adhesive at the inter-substrate coupling portion 160. The adhesive may be appropriately selected depending on the materials of the upper drive beam 112u and the lower drive beam 112v.

In the case where the drive portion such as a piezoelectric film is formed in a multilayer in order to displace the movable portion by a large displacement amount, the film is formed in a multilayer by a film forming process such as physical vapor deposition, sputtering, or chemical vapor deposition. In the film forming process, in order to form a film with high accuracy, it is necessary to optimize the manufacturing process or various parameters for each manufacturing process. Thus, the difficulty of the method for manufacturing the movable device may be increased. As the difficulty level of the method for manufacturing increases, the yield of the movable device may decrease.

In the movable device 13, since the upper drive beam 112u and the lower drive beam 112v are mechanically coupled by an adhesive, the upper drive beam 112u and the lower drive beam 112v can be coupled more easily than in the film forming process. Thus, the movable device 13 that can obtain a large displacement amount while increasing the displacement stability can be easily manufactured. In addition, the yield of the movable device 13 can be increased by simplifying the manufacturing.

In the movable device 13, the movable portion 101 is disposed so as to be spaced from either the upper drive beam 112u or the lower drive beam 112v in the normal direction of the fixed frame 140. In the movable device 13, the movable portion 101 is disposed so as to be spaced from either the upper drive beam 112u or the lower drive beam 112v in the top view. Accordingly, the movable device 13 can be reduced in size as compared with the case where the movable portion 101 is disposed so as not to overlap with either the upper drive beam 112u or the lower drive beam 112v in a top view. In addition, the movable device 13 is reduced in size so that the resonance frequency in the oscillation of the movable portion 101 about the second axis E2 as the rotation axis can become higher.

The one end 135 of the drive beam 112 may not be coupled to the movable portion 101 indirectly via the support portion 120, but may be coupled directly to the movable portion 101.

A configuration of the movable device 13 will be described in detail below.

The movable portion 101 includes a movable portion base 102 and a mirror surface 14 disposed above the movable portion base 102. The mirror surface 14 reflects a light beam incident on the mirror surface 14. The movable device 13 can oscillate the movable portion 101 about the first axis E1 as the rotation axis and oscillate the movable portion 101 about the second axis E2 as the rotation axis. The inclination of the mirror surface 14 changes in accordance with the oscillation of the movable portion 101. The movable device 13 changes the inclination of the mirror surface 14 by oscillating the movable portion so that the movable device can deflect the light beam incident on the mirror surface 14 and scan an object with the light beam in the direction along the first axis E1 and the second axis E2.

The support portion 120 includes a first torsion bar spring 111a, a second torsion bar spring 111b, a third drive portion 112a, and a fourth drive portion 112b. The support portion 120 supports the movable portion 101 and oscillates the movable portion 101 about the first axis E1 as a rotation axis by the third drive portion 112a and the fourth drive portion 112b. The support portion 120 includes, for example, a silicon support layer 361a, a silicon oxide layer 361b, and a silicon active layer 361c. The support portion 120 includes a frame having a substantially rectangular outer edge shape in a top view. The frame of the support portion 120 surrounds the movable portion 101, the third drive portion 112a, and the fourth drive portion 112b in a top view.

The first torsion bar spring 111a and the second torsion bar spring 111b are torsion beams. In the example illustrated in FIG. 1, the first torsion bar spring 111a is disposed in the −X-direction of the movable portion 101. One end of the first torsion bar spring 111a is coupled to the movable portion 101. The other end of the first torsion bar spring 111a is coupled to a base member on which the third drive portion 112a is disposed via the drive portion coupling portion 113a. The second torsion bar spring 111b is disposed at the movable portion 101 in the +X-direction. One end of the second torsion bar spring 111b is coupled to the movable portion 101. The other end of the second torsion bar spring 111b is coupled to the base member on which the fourth drive portion 112b is disposed via the drive portion coupling portion 113b. The third drive portion 112a drives the movable portion 101 via the first torsion bar spring 111a. The fourth drive portion 112b drives the movable portion 101 via the second torsion bar spring 111b.

The fixed frame 140 is a frame member having a substantially rectangular outer edge shape in a top view. The movable portion 101, the drive beam 112, and the support portion 120 are disposed inside the fixed frame 140. The electrode connecting portions 150 are disposed at an +X-side end on the +Z-side surface of the fixed frame 140. The electrode connecting portions 150 electrically connect the first drive portion 131-1, the second drive portion 131-2, the third drive portion 112a, and the fourth drive portion 112b to a control device that controls the driving of the movable device 13. The drive voltage from the control device is applied to the first drive portion 131-1, the second drive portion 131-2, the third drive portion 112a, and the fourth drive portion 112b via the electrode connecting portions 150.

As illustrated in FIG. 3, the movable device 13 is formed by bonding two SOI substrates, i.e., the first SOI substrate 361 and the second SOI substrate 362, with a silicon oxide layer 363 put therebetween. An upper electrode 201, a lower electrode 203, and a piezoelectric portion 202 put between the lower electrode 203 and the upper electrode 201 are formed on the surfaces of the first SOI substrate 361 and the second SOI substrate 362. Each drive portion included in the drive portion 131 includes a piezoelectric portion 202 put between a lower electrode 203 and an upper electrode 201.

Each of the first SOI substrate 361 and the second SOI substrate 362 is a substrate in which a silicon oxide layer is disposed above a first silicon layer made of single-crystal silicon (Si), and a second silicon layer made of single-crystal silicon is further disposed above the silicon oxide layer. In the following description, the first silicon layer is referred to as a silicon support layer 361a and a silicon support layer 362a, and the second silicon layer is referred to as a silicon active layer 361c and a silicon active layer 362c.

The first SOI substrate 361 includes the silicon support layer 361a, the silicon oxide layer 361b, and the silicon active layer 361c. The second SOI substrate 362 includes the silicon support layer 362a, the silicon oxide layer 362b, and the silicon active layer 362c. The first SOI substrate 361 and the second SOI substrate 362 are formed by etching. The mirror surface 14, the first drive portion 131-1, the second drive portion 131-2, the third drive portion 112a, the fourth drive portion 112b, and the electrode connecting portions 150 are formed above each of the first SOI substrate 361 and the second SOI substrate 362, so that these portions can be integrally formed in one body. The above-described portions may be formed after the formation of the first SOI substrate 361 and the second SOI substrate 362, or may be formed during the formation of the first SOI substrate 361 and the second SOI substrate 362. The method for bonding the two SOI substrates, i.e., the first SOI substrate 361 and the second SOI substrate 362, is not limited to bonding with an adhesive, and may be joining. In the case of bonding, the silicon oxide layer 363 serves as an adhesive.

Since the silicon active layer 361c has a small thickness in the Z-direction relative to the X-direction and the Y-direction, a member including only the silicon active layer 361c has a function as an elastic portion having elasticity. The first SOI substrate 361 and the second SOI substrate 362 may not be planar, but may have curvature. The base member used for forming the movable device 13 is not limited to the SOI substrate as long as the base member can be integrally formed as one body by etching and can be partially given elasticity.

The details of the main scanning structure for performing oscillation with the first axis E1 as the rotation axis will be described. The movable portion base 102 includes, for example, a silicon active layer 361c. The mirror surface 14 includes a thin metal film containing, for example, aluminum, gold, or silver. In the movable portion 101 illustrated in FIG. 4, a rib 103 for reinforcing the mirror portion is formed at the −Z-side surface of the movable portion base 102. The rib 103 includes, for example, a silicon support layer 361a, and a silicon oxide layer 361b. The rib 103 can reduce the distortion of the mirror surface 14 caused when the movable portion 101 is oscillated.

The fourth driving portion 112b illustrated in FIG. 3 is formed by laminating an upper electrode 201, a piezoelectric portion 202, and a lower electrode 203 in this order above the +Z-side surface of a silicon active layer 361c that is an elastic portion. The upper electrode 201 and the lower electrode 203 are made of, for example, gold (Au) or platinum (Pt). The piezoelectric portion 202 is made of, for example, lead zirconate titanate (PZT) that is a piezoelectric material. The configuration of the third drive portion 112a is also the same as that of the fourth drive portion 112b.

As illustrated in FIG. 4, the first torsion bar spring 111a and the second torsion bar spring 111b are members extending in the direction along the first axis E1. The first torsion bar spring 111a and the second torsion bar spring 111b include the silicon active layer 361c of the first SOI substrate 361. Each of the third drive portion 112a and the fourth drive portion 112b has a unimorph structure and is deformed only in one direction by the application of a drive voltage. However, the movable device 13 can reciprocally oscillate the movable portion 101 supported by the support portion 120 by the action of the respective springs of the first torsion bar spring 111a and the second torsion bar spring 111b. The oscillation of the movable portion 101 about the first axis E1 as the rotation axis is resonant oscillation. The resonance frequency is designed using information such as the moment of inertia of the movable portion 101 or the rigidity of the first torsion bar spring 111a and the second torsion bar spring 111b.

As illustrated in FIG. 4, the torsion center axis C0 of the first torsion bar spring 111a and the second torsion bar spring 111b is offset from the first axis E1 passing through the center of the movable portion 101. Due to this offset, the movable device 13 changes the Z-directional displacement of the tip in the +Y-direction of the base member at which the third drive portion 112a and the fourth drive portion 112b are disposed into a rotational force (moment) to oscillate the movable portion 101. In the example illustrated in FIG. 4, the torsion center axis C0 is the torsion center axis of the first torsion bar spring 111a and the torsion center axis of the second torsion bar spring 111b. The offset ΔS represents an offset amount of the torsion center axis C0 with respect to the first axis E1.

The base member at which the third drive portion 112a and the fourth drive portion 112b are disposed has a free end at the tip thereof, and a large displacement can be obtained without preventing the piezoelectric driving force. Further, the bending mode resonance of the base member at which the third drive portion 112a and the fourth drive portion 112b are disposed is set in the vicinity of the torsional mode resonance of each of the first torsion bar spring 111a and the second torsion bar spring 111b so that the rotation angle of the movable portion 101 can be greatly increased, and a large displacement can be obtained even when a low drive voltage is applied.

The structure for performing oscillation with the second axis E2 as a rotation axis will be described in detail. The oscillation of the movable portion 101 about the first axis E1 as the rotation axis is resonant oscillation. Thus, the waveform of the drive voltage becomes a sine wave. In many cases, the movable portion 101 performs a constant-speed oscillation with the second axis E2 as the rotation axis. In addition, a sawtooth waveform is often used for the waveform of the drive voltage. In order to perform the constant-speed oscillation by the drive voltage having the sawtooth waveform, it is preferable to perform the non-resonant oscillation. In the non-resonant oscillation, a large displacement as in the resonant oscillation is difficult to obtain. In the oscillation with the second axis E2 as the rotation axis, it is preferable that the drive beam is deformed in both directions. As described above, the structure of the drive beam is a meander structure in which multiple drive beams are folded back. The meander structure allows the drive beam to be deformed in both directions by performing oscillation of two channels, i.e., the A channel and the B channel. Further, the displacement of the movable portion 101 can be increased by accumulating the deformations of the multiple drive beams.

In the example illustrated in FIGS. 1 to 3, the upper drive beam 112u is formed with the first SOI substrate 361. The second SOI substrate 362 forms the lower drive beam 112v. The upper drive portion 131u is formed in the silicon active layer 361c of the first SOI substrate 361. The lower drive portion 131v is formed in the silicon active layer 362c of the second SOI substrate 362. Each of the upper drive beam 112u and the lower drive beam 112v has a meander structure.

A first end 135-1 at which a first upper drive beam 112u-1 is coupled to a movable portion 101, a second end 135-2 at which a second upper drive beam 112u-2 is coupled to the movable portion 101, a coupling portion at which the first upper drive beam 112u-1 is coupled to the first lower drive beam 112v-1, a coupling portion at which the second upper drive beam 112u-2 is coupled to the second lower drive beam 112v-2, a coupling portion at which the first lower drive beam 112v-1 is coupled to a fixed frame 140, and a coupling portion at which the second lower drive beam 112v-2 is coupled to the fixed frame 140 are point symmetric with respect to the center of the mirror surface 14.

As illustrated in FIG. 2, the first upper drive portion 131u-1 and the second upper drive portion 131u-2 are formed by laminating a lower electrode 203, a piezoelectric portion 202, and an upper electrode 201 in this order above the surface of the silicon active layer 361c, which is an elastic portion, in the +Z-direction. The first lower drive portion 131v-1 and the second lower drive portion 131v-2 are formed by laminating a lower electrode 203, a piezoelectric portion 202, and an upper electrode 201 in this order above the surface of the silicon active layer 362c, which is an elastic portion, in the +Z-direction. The upper electrode 201 and the lower electrode 203 are made of, for example, gold (Au) or platinum (Pt). The piezoelectric portion 202 is made of, for example, lead zirconate titanate (PZT) that is a piezoelectric material.

In the example illustrated in FIGS. 1 and 3, the fixed frame 140 is formed by bonding two SOI substrates, i.e., the first SOI substrate 361 and the second SOI substrate 362, with the silicon oxide layer 363 put therebetween.

In the example illustrated in FIG. 5, the upper drive beam 112u is electrically connected to the lower drive beam 112v via wire bonding 161. In another aspect, in the inter-substrate coupling portion 160, electrical wiring is formed between the first SOI substrate 361 and the second SOI substrate 362 via wire bonding 161 in order to apply a drive voltage to the piezoelectric portion 202. Since the upper drive beam 112u and the lower drive beam 112v are electrically connected via the wire bonding 161, the wiring between the first SOI substrate 361 and the second SOI substrate 362 that are different substrates can be performed. Since the wiring between the first SOI substrate 361 and the second SOI substrate 362 is performed, a drive voltage can be applied to each of the upper drive beam 112u and the lower drive beam 112v. The upper electrode 201 and the lower electrode 203 may be directly connected to the electrode connecting portions 150, or may be indirectly connected to the electrode connecting portions 150 by connecting the electrodes to each other.

The piezoelectric portion 202 is not limited to the configuration of being formed only on the +Z-side surface of the silicon active layer 361c, which is an elastic portion. The piezoelectric portion 202 may be disposed on the −Z-side surface of the silicon active layer 361c or may be disposed on both the +Z-side surface and the −Z-side surface of the silicon active layer 361c. Each piezoelectric portion 202 may be formed of a multilayer piezoelectric film instead of a single layer.

The shapes of the components are not limited to the shapes illustrated in FIGS. 1 to 5 as long as the movable portion 101 can oscillate about the first axis E1 and the second axis E2. For example, the shapes of the first torsion bar spring 111a, the second torsion bar spring 111b, the upper drive beam 112u, and the lower drive beam 112v may have curvatures.

An insulating layer made of a silicon oxide film may be formed on at least one of the +Z-side surfaces of the upper electrodes 201 of the upper drive portion 131u, the lower drive portion 131v, the third drive portion 112a, and the fourth drive portion 112b, the +Z-side surface of the support portion 120, and the +Z-side surface of the fixed frame 140. In the case of forming an insulating layer, electrode wiring may be disposed above the insulating layer, and only a connection spot at which the upper electrode 201 or the lower electrode 203 is connected to the electrode wiring may be formed by partially removing the insulating layer as an opening or not forming the insulating layer. Accordingly, the degree of freedom in designing the upper drive portion 131u, the lower drive portion 131v, the third drive portion 112a, the fourth drive portion 112b, and the electrode wiring can be increased, and can reduce short circuits due to contact between electrodes. The silicon oxide film also functions as an anti-reflection material.

### Oscillation of Movable Portion in Movable Device

The oscillation of the movable portion 101 by the upper drive portion 131u, the lower drive portion 131v, the third drive portion 112a, and the fourth drive portion 112b in the movable device 13 will be described in detail.

In the movable device 13, in order to oscillate the movable portion 101, a positive or negative drive voltage is applied to the piezoelectric portions 202 of the upper drive portion 131u, the lower drive portion 131v, the third drive portion 112a, and the fourth drive portion 112b with respect to the polarization direction. The drive voltage causes the piezoelectric portion 202 to deform (e.g., expand or contract) in proportion to the potential of the applied drive voltage, and what is called an inverse piezoelectric effect is obtained. Each of the upper drive portion 131u, the lower drive portion 131v, the third drive portion 112a, and the fourth drive portion 112b oscillates the movable portion 101 by utilizing the inverse piezoelectric effect.

In the following description, an angle formed by the mirror surface 14 of the movable portion 101 and the XY-plane when the mirror surface 14 is tilted in the +Z-direction or the −Z-direction with respect to the XY-plane is referred to as a deflection angle. A direction in which the +X-side of the movable portion 101 is tilted in the +Z-direction is defined as a positive deflection angle, and a direction in which the +X-side of the movable portion 101 is tilted in the −Z-direction is defined as a negative deflection angle.

### Oscillation by the Third Drive Portion and the Fourth Drive Portion

The driving of the movable portion 101 by the third driving portion 112a and the fourth driving portion 112b will be described. In the third drive portion 112a and the fourth drive portion 112b, when a drive voltage is applied in parallel to the piezoelectric portions 202 of the third drive portion 112a and the fourth drive portion 112b via the upper electrode 201 and the lower electrode 203, the piezoelectric portions 202 are deformed. The third drive portion 112a and the fourth drive portion 112b are bent and deformed by the deformation of the piezoelectric portion 202. The third drive portion 112a and the fourth drive portion 112b are bent and deformed so that the first torsion bar spring 111a and the second torsion bar spring 111b are twisted. A driving force about the first axis E1 as a rotation axis acts on the movable portion 101 in accordance with the torsion of each of the first torsion bar spring 111a and the second torsion bar spring 111b. When this driving force acts, the movable portion 101 oscillates about the first axis E1 as a rotation axis.

The drive voltages applied to the third drive portion 112a and the fourth drive portion 112b are controlled by a control device. For example, a drive voltage having a predetermined sinusoidal waveform is applied to the third drive portion 112a and the fourth drive portion 112b in parallel from the control device so that the movable portion 101 can be oscillated about the first axis E1 as a rotation axis at a cycle of the drive voltage having a sinusoidal waveform. When the frequency of the sinusoidal waveform voltage is set to about 20 kilohertz (kHz) that is substantially equal to the resonance frequency of the first torsion bar spring 111a and the second torsion bar spring 111b, the movable portion 101 can be resonantly oscillated at about 20 kHz by utilizing the occurrence of mechanical resonance due to the torsion of the first torsion bar spring 111a and the second torsion bar spring 111b. The movable portion 101 is resonantly oscillated so that a large displacement of the movable portion 101 can be obtained even when a small drive voltage is applied.

Oscillation by the Upper Drive Portion and the Lower Drive Portion The oscillation of the movable portion 101 by the upper drive portion 131u and the lower drive portion 131v will be described with reference to FIG. 1 and FIGS. 6 to 12. In the movable device 13, since the first upper drive portion 131u-1, the second upper drive portion 131u-2, the first lower drive portion 131v-1, and the second lower drive portion 131v-2 have the same shape and perform substantially the same function, the oscillation of the movable portion 101 by the second upper drive portion 131u-2 will be described as a representative.

In order to describe the oscillation by the upper drive portion 131u, as illustrated in FIG. 1, the second upper drive portion 132a and the second upper drive portion 132c, which are odd-numbered from the second upper drive portion 132a closest to the movable portion 101 among the second upper drive portion 132a, the second upper drive portion 132b, the second upper drive portion 132c, and the second upper drive portion 132d, are similarly referred to as a drive portion group 200A. In addition, the second upper drive portion 132b and the second upper drive portion 132d, which are even-numbered from the second upper drive portion 132a closest to the movable portion 101 among the second upper drive portion 132a, the second upper drive portion 132b, the second upper drive portion 132c, and the second upper drive portion 132d, are similarly referred to as a drive portion group 200B.

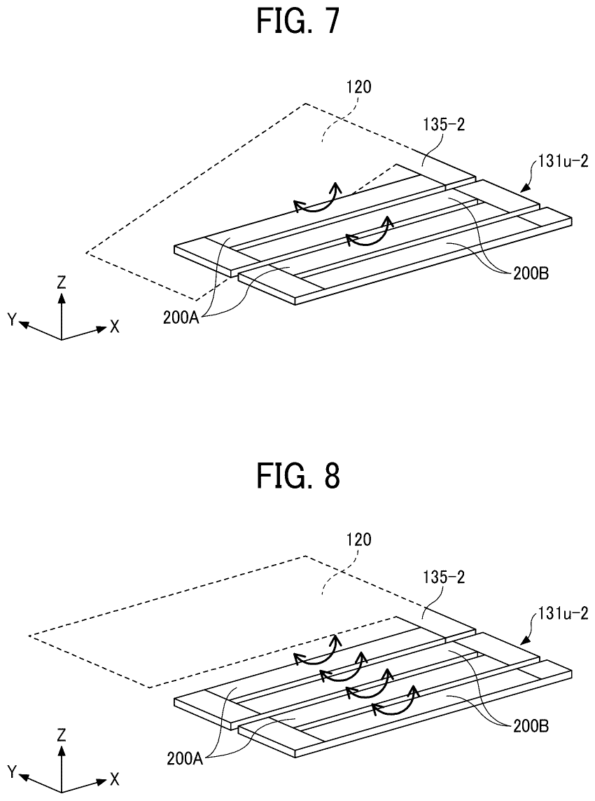

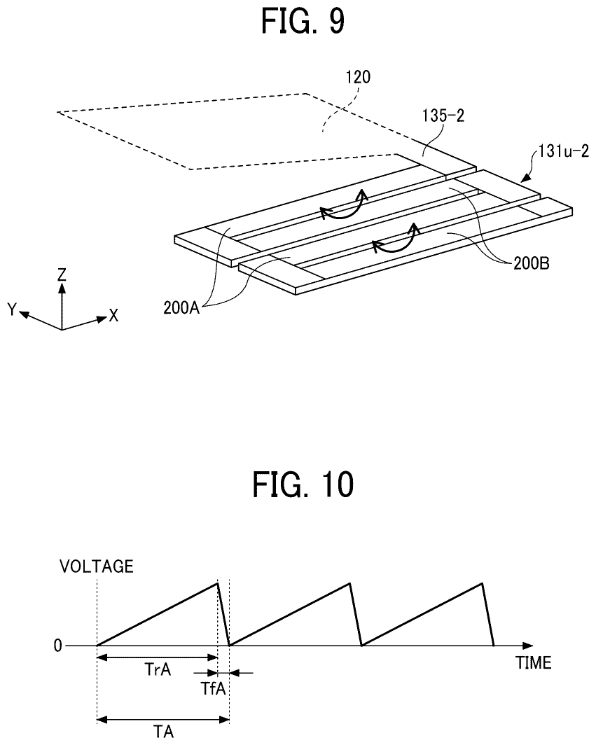

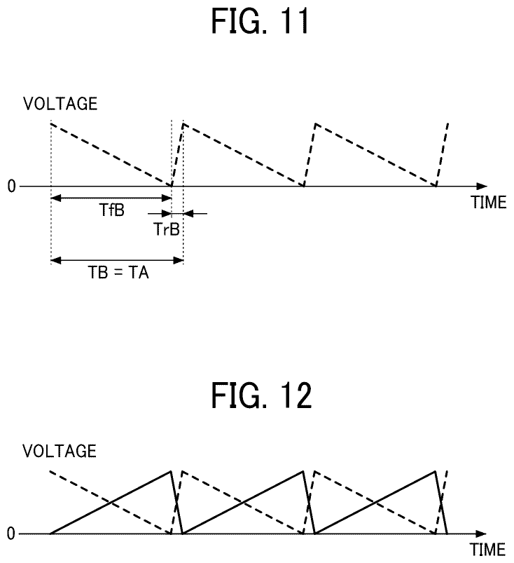

FIG. 6 is a first schematic perspective view of an example of a state in which the movable portion 101 is oscillated by the second upper drive portion 131u-2 in the movable device 13 according to the first embodiment of the present disclosure. FIG. 7 is a second schematic perspective view of an example of a state in which the movable portion 101 is oscillated by the second upper drive portion 131u-2 in the movable device 13 according to the first embodiment of the present disclosure. FIG. 8 is a third schematic perspective view of an example of a state in which the movable portion 101 is oscillated by the second upper drive portion 131u-2 in the movable device 13 according to the first embodiment of the present disclosure. FIG. 9 is a fourth schematic perspective view of an example of a state in which the movable portion 101 is oscillated by the second upper drive portion 131u-2 in the movable device 13 according to the first embodiment of the present disclosure. FIG. 10 is a first diagram illustrating a waveform of a drive voltage applied to the drive portion group 200A of the movable device 13 according to the first embodiment of the present disclosure. FIG. 11 is a second diagram illustrating a waveform of a drive voltage applied to the drive portion group 200B of the movable device 13 according to the first embodiment of the present disclosure. FIG. 12 is a diagram illustrating a waveform in which the waveform of the drive voltage of FIG. 10 and the waveform of the drive voltage of FIG. 11 are superimposed.

FIGS. 6 to 9 are diagrams illustrating a state where the support portion 120 coupled to the second upper drive portion 131u-2 is oscillated by the second upper drive portion 131u-2. The support portion 120 is represented by a broken line. The support portion 120 is oscillated so that the movable portion 101 supported by the support portion 120 is oscillated together with the support portion 120.

As illustrated in FIG. 6, in a state in which no drive voltage is applied to the second upper drive portion 131u-2, the deflection angle of the movable portion 101 due to the support portion 120 oscillated by the second upper drive portion 131u-2 is zero. A virtual plane including the outer edge of the support portion 120 in a top view is substantially parallel to the XY-plane, and the mirror surface 14 of the movable portion 101 supported by the support portion 120 is substantially parallel to the XY-plane.

As illustrated in FIG. 7, when a drive voltage is applied to the drive portion group 200A in parallel, the drive portion group 200A is bent and deformed in the same direction, and the support portion 120 tilts in the negative direction with the second axis E2 as the rotation axis.

As illustrated in FIG. 8, when the displacement amount of the support portion 120 by the drive portion group 200A by voltage application and the displacement amount of the support portion 120 by the drive portion group 200B by voltage application are balanced, the deflection angle is zero.

As illustrated in FIG. 9, when a drive voltage is applied to the drive portion group 200B in parallel, the drive portion group 200B is bent and deformed in the same direction, and the movable portion 101 is oscillated in the +Z-direction about the second axis E2 as the rotation axis.

A drive voltage is applied to the second upper drive portion 131u-2 so as to continuously repeat the displacement illustrated in FIGS. 7 to 9 so that the support portion 120 can be oscillated about the second axis E2, and the movable portion 101 supported by the support portion 120 can be oscillated around the second axis E2.

As illustrated in FIGS. 7 and 9, the multiple piezoelectric portions 202 of the drive portion group 200A are simultaneously bent and deformed or the multiple piezoelectric portions 202 of the drive portion group 200B are simultaneously bent and deformed, so that the displacement amount due to the bend and deformation is accumulated and the deflection angle of the support portion 120 with the second axis E2 as the rotation axis can be increased. In the movable device 13, the upper drive portion 131u and the lower drive portion 131v are coupled in point symmetry with respect to the center point of the mirror surface 14 that coincides with the center point of the support portion 120. Thus, when a drive voltage is applied to the drive portion group 200A, a driving force that moves the movable portion 101 in the +Z-direction is generated at the second end 135-2 of the second upper drive portion 131u-2 coupled to the support portion 120, and a driving force that moves the movable portion 101 in the −Z-direction is generated at the first end 135-1 of the first upper drive portion 131u-1 coupled to the support portion 120. The displacement amounts of the first upper drive portion 131u-1 and the second upper drive portion 131u-2 are accumulated, and the deflection angle of the movable portion 101 supported by the support portion 120 with respect to the second axis E2 as the rotation axis can be increased.

The displacement amount is accumulated in the lower drive portion 131v as well. In the movable device 13, the displacement amounts of the upper drive portion 131u and the lower drive portion 131v are accumulated, and a larger displacement amount can be obtained. The oscillation of the movable portion 101 by the upper drive beam 112u and the lower drive beam 112v is not limited to the non-resonant oscillation, and may be resonant oscillation. Even when the oscillation of the movable portion 101 by the upper drive beam 112u and the lower drive beam 112v is non-resonant oscillation, a large displacement amount can be obtained by accumulating the displacement amounts of the upper drive portion 131u and the lower drive portion 131v.

In the movable device 13, the upper drive beam 112u is driven by an antiphase drive voltage having a phase opposite to the drive voltage that drives the lower drive beam 112v. Accordingly, there is no need to arrange an A channel and a B channel in the same substrate as in the meander structure, and the movable device 13 can be formed in a smaller size.

The drive voltages applied to the upper drive portion 131u and the lower drive portion 131v are controlled by the control device. The drive voltages applied to the drive portion group 200A and the drive portion group 200B will be described with reference to FIGS. 10 to 12.

FIG. 10 is a first diagram illustrating a waveform of a drive voltage applied to the drive portion group 200A of the movable device 13 according to the first embodiment of the present disclosure. FIG. 11 is a second diagram illustrating a waveform of a drive voltage applied to the drive portion group 200B of the movable device 13 according to the first embodiment of the present disclosure. FIG. 12 is a diagram illustrating a waveform in which the waveform of the drive voltage illustrated in FIG. 10 and the waveform of the drive voltage illustrated in FIG. 11 are superimposed.

As illustrated in FIG. 10, the drive voltage applied to the drive portion group 200A is, for example, a drive voltage having a sawtooth waveform. The frequency is, for example, 60 hertz (Hz). The waveform of the drive voltage applied to the drive portion group 200A has a predetermined ratio of, for example, TrA:TfA=9:1, where TrA is the time width of the rising period in which the voltage value increases from the minimum value to the next maximum value, and TfA is the time width of the falling period in which the voltage value decreases from the maximum value to the next minimum value. The ratio of TrA to one cycle is referred to as symmetry of the drive voltage applied to the drive portion group 200A.

As illustrated in FIG. 11, the drive voltage applied to the drive portion group 200B is, for example, a drive voltage having a sawtooth waveform. The frequency is, for example, 60 Hz. The waveform of the drive voltage applied to the drive portion group 200B has a predetermined ratio of, for example, TfB:TrB=9:1, where TrB is the time width of the rising period in which the voltage value increases from the minimum value to the next maximum value, and TfB is the time width of the falling period in which the voltage value decreases from the maximum value to the next minimum value. The ratio of TfB to one cycle is referred to as symmetry of the drive voltage B. As illustrated in FIG. 12, for example, the period TA of the waveform of the drive voltage applied to the drive portion group 200A and the period TB of the waveform of the drive voltage applied to the drive portion group 200B are set to be the same.

The sawtooth waveforms of the drive voltage applied to the drive portion group 200B and the drive voltage applied to the drive portion group 200B are generated by the superposition of sine waves. However, the drive voltage applied to the drive portion group 200B and the drive voltage applied to the drive portion group 200B are not limited to the drive voltage having sawtooth waveforms. The waveform may be appropriately changed according to the device characteristics of the movable device 13, such as a drive voltage having a waveform in which the apex of the sawtooth waveform is rounded, a drive voltage having a waveform in which the straight region of the sawtooth waveform is curved.

### Second Embodiment

A movable device according to a second embodiment of the present disclosure will be described. The same reference numerals and symbols as those of the above-described embodiments denote the same or similar members or structures, and detailed descriptions thereof will be omitted. This point is also applied to other embodiments described below.

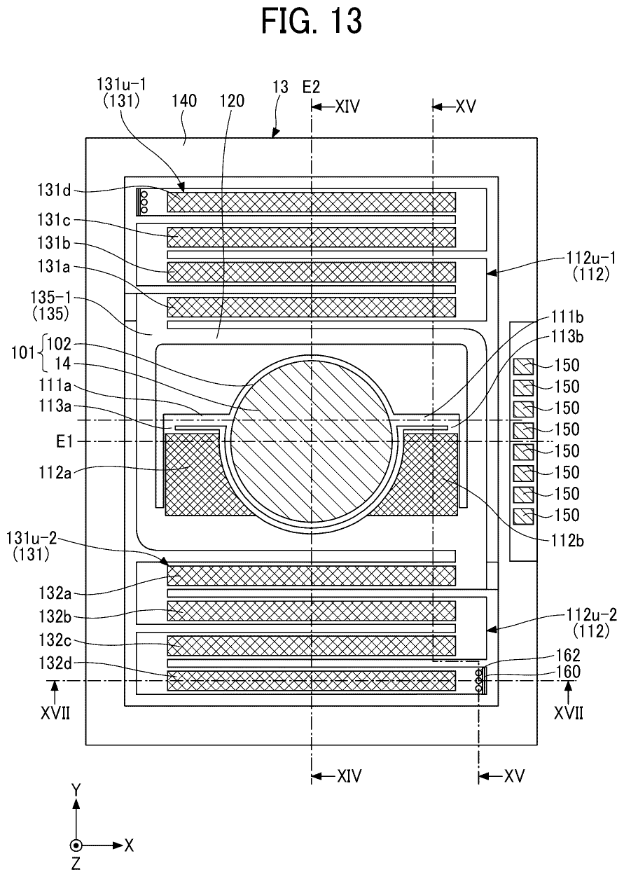

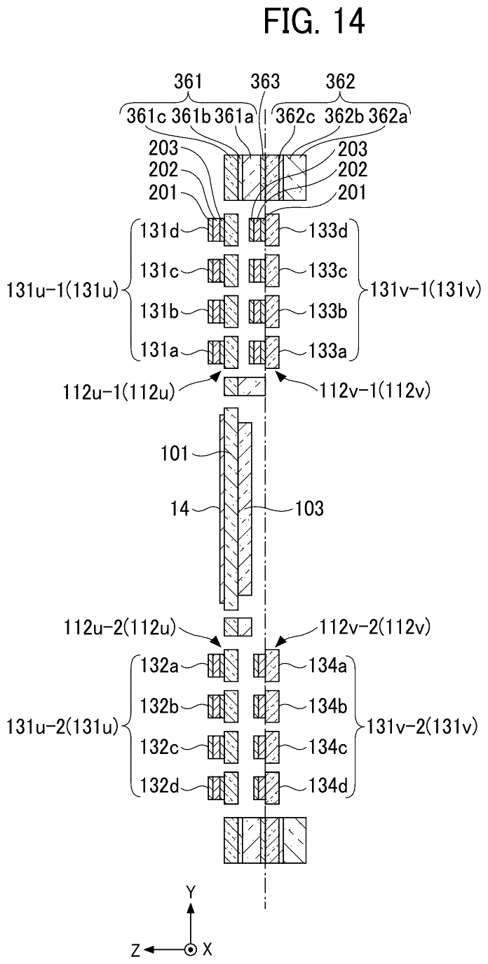

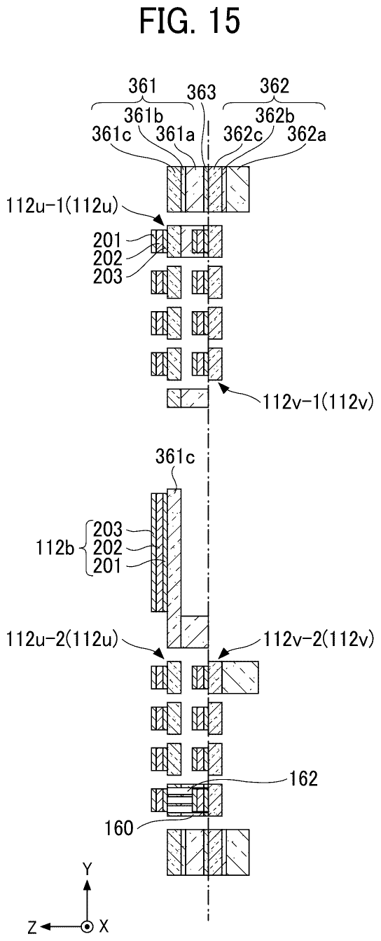

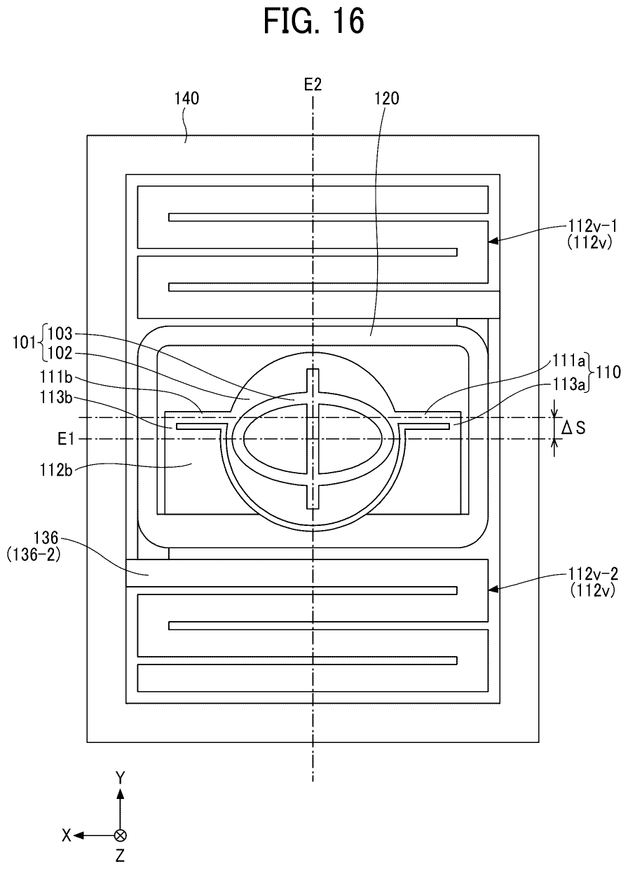

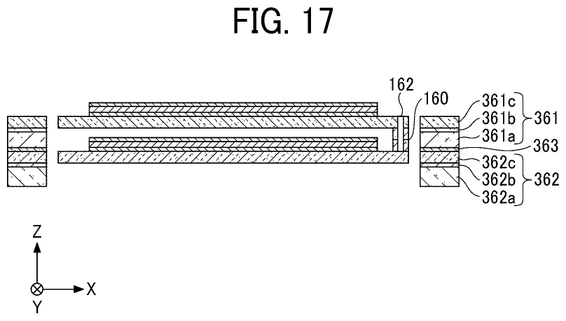

The structure of a movable device according to a second embodiment of the present disclosure will be described with reference to FIGS. 13 to 17. FIG. 13 is a schematic top view of an example of the movable device 13 according to the second embodiment of the present disclosure. FIG. 14 is a schematic cross-sectional view of the movable device 13 taken along the line XIV-XIV in FIG. 13. FIG. 15 is a schematic cross-sectional view of the movable device 13 taken along the line XV-XV in FIG. 13. FIG. 16 is a schematic bottom view of an example of the movable device 13 according to the second embodiment of the present disclosure. FIG. 17 is a schematic cross-sectional view of the movable device 13 taken along the line XVII-XVII in FIG. 13.

The movable device 13 according to the second embodiment of the present disclosure differs from the movable device 13 according to the first embodiment in that the upper drive beam 112u is electrically connected to the lower drive beam 112v via a through-silicon via (TSV) 162. The through-silicon via 162 is an electrode that passes through a hole formed in a silicon substrate to connect upper and lower chips.

Since the upper drive beam 112u and the lower drive beam 112v are electrically connected via the through-silicon via 162, the wiring between the first SOI substrate 361 and the second SOI substrate 362 that are different substrates can be performed. Since the wiring between the first SOI substrate 361 and the second SOI substrate 362 is performed, a drive voltage can be applied to each of the upper drive beam 112u and the lower drive beam 112v.

### Third Embodiment

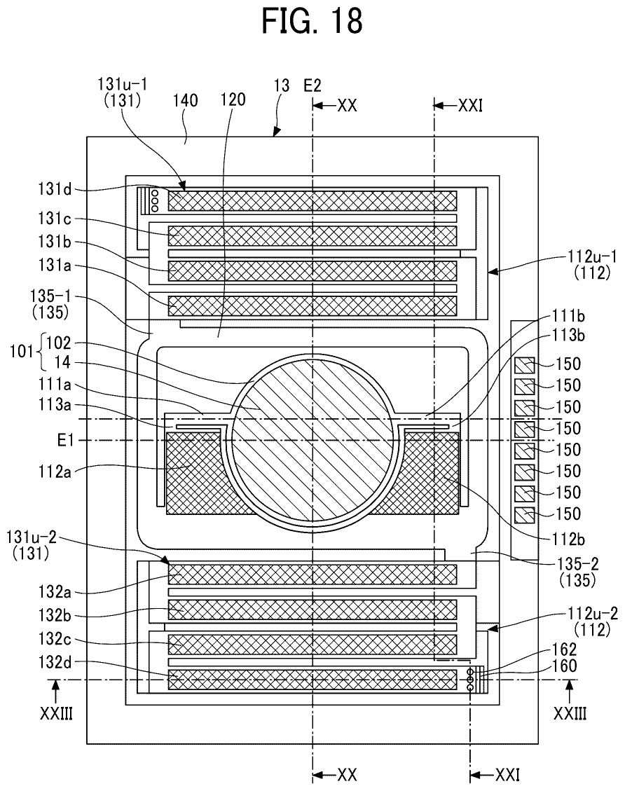

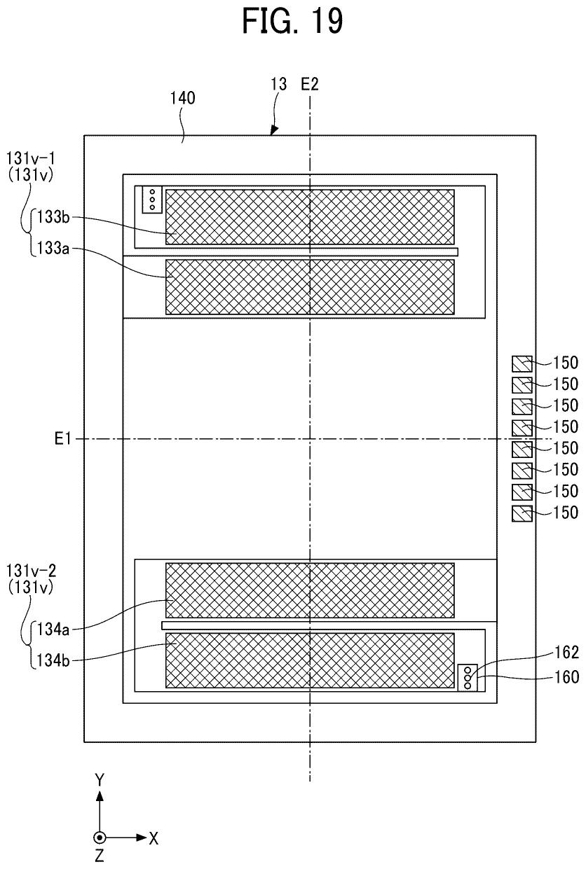

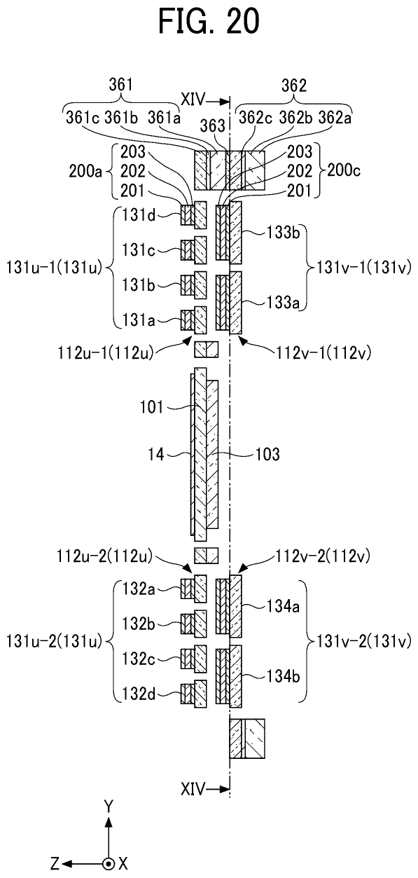

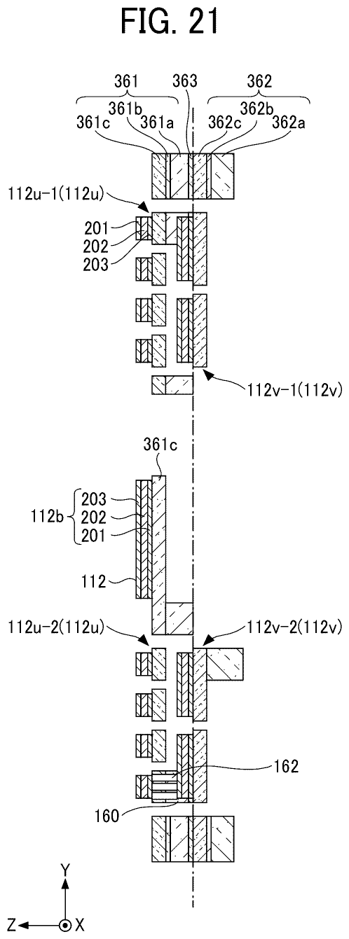

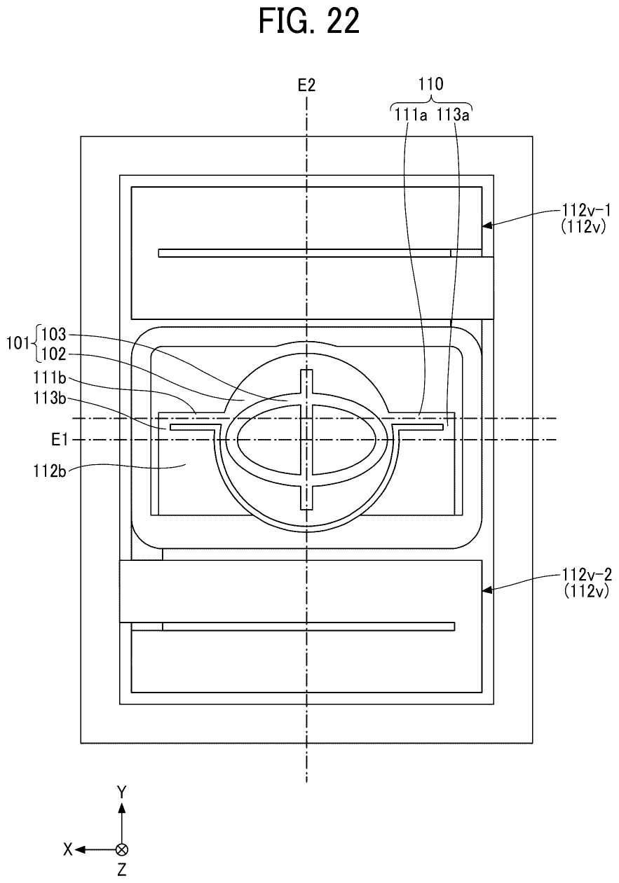

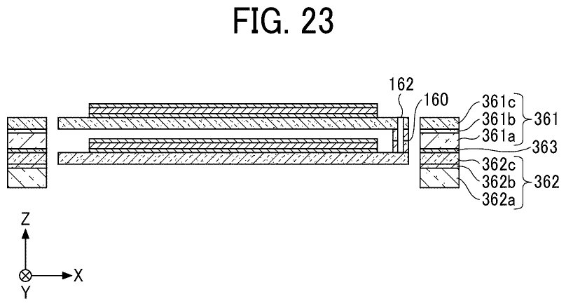

A movable device according to a third embodiment of the present disclosure will be described with reference to FIGS. 18 to 23. FIG. 18 is a schematic top view of an example of the movable device 13 according to the third embodiment of the present disclosure. FIG. 19 is a schematic top view of the movable device 13 taken along the line XIX-XIX in FIG. 20. FIG. 20 is a schematic cross-sectional view of the movable device 13 taken along the line XX-XX in FIG. 18. FIG. 21 is a schematic cross-sectional view of the movable device 13 taken along the line XXI-XXI in FIG. 18. FIG. 22 is a schematic bottom view of an example of the movable device 13 according to the third embodiment of the present disclosure. FIG. 23 is a schematic cross-sectional view of the movable device taken along the line XXIII-XXIII in FIG. 18.

The movable device 13 according to the third embodiment differs from the movable device 13 according to the first embodiment of the present disclosure in that the shape of the upper drive beam 112u and the shape of the lower drive beam 112v are different from each other.

In the example illustrated in FIG. 19, among the multiple drive beams of the lower drive beam 112v, the width of the drive beam on the side closer to the fixed frame 140 is widened to increase the partial rigidity, and the width of the drive beam on the side closer to the support portion 120 is narrowed to decrease the partial rigidity. Accordingly, the resonance frequency can become higher. The higher resonance frequency becomes can stabilize the operation of the movable device 13.

The thickness of the silicon active layer 362c of the second SOI substrate 362 is formed thicker than the thickness of the silicon active layer 361c of the first SOI substrate 361 so that the thickness of the lower drive beam 112v may be formed thicker than the thickness of the upper drive beam 112u. Also, according to this configuration, the resonance frequency can become higher, and the operation of the movable device 13 can be stabilized.

### Fourth Embodiment

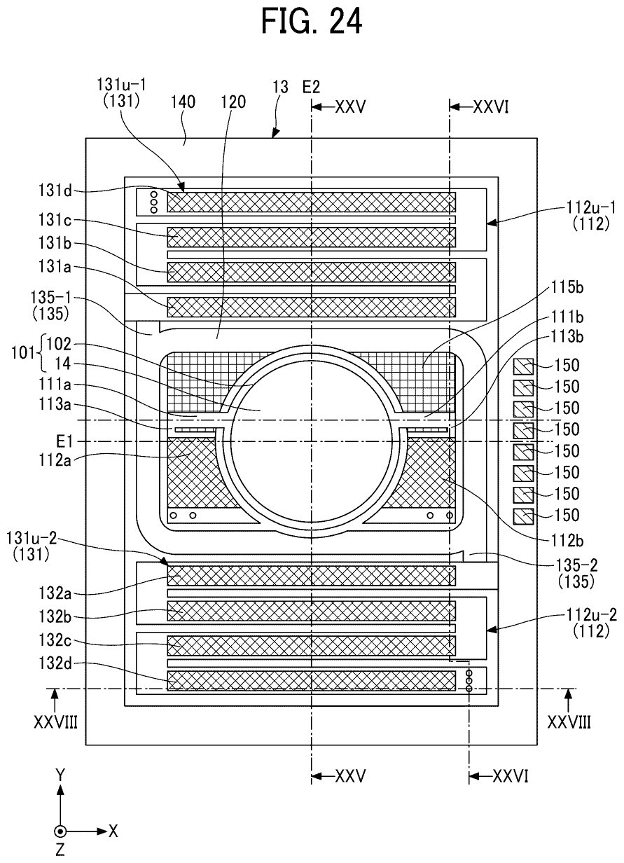

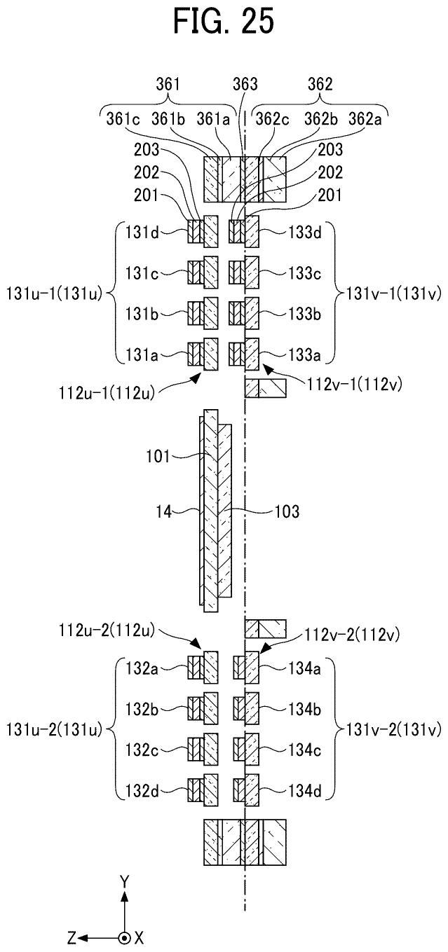

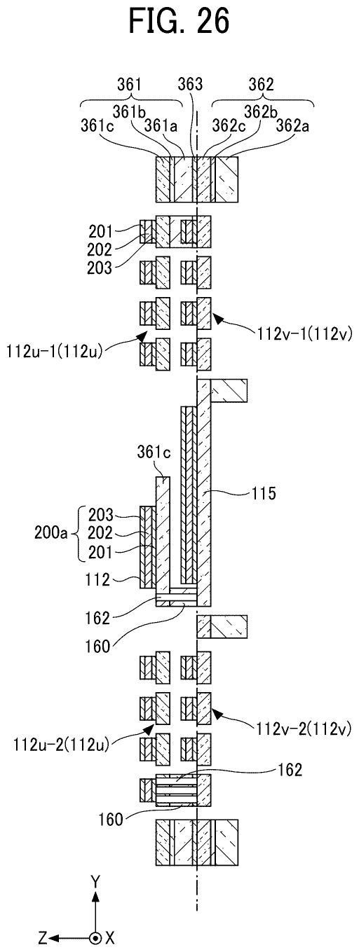

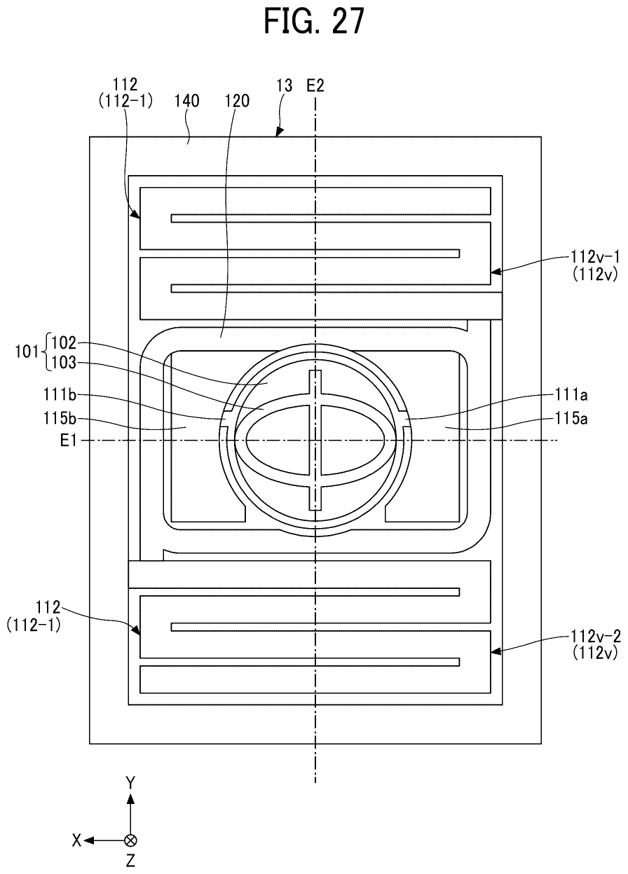

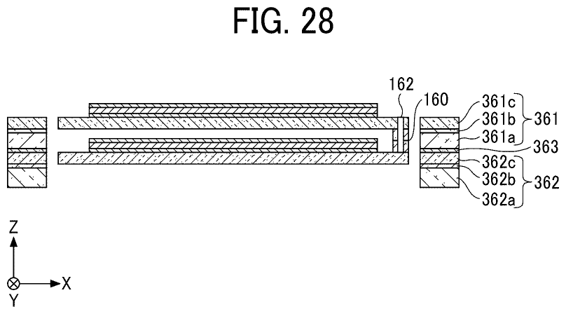

A movable device according to a fourth embodiment of the present disclosure will be described with reference to FIGS. 24 to 28. FIG. 24 is a schematic top view of an example of the movable device 13 according to the fourth embodiment of the present disclosure. FIG. 25 is a schematic cross-sectional view of the movable device 13 taken along the line XXV-XXV in FIG. 24; FIG. 26 is a schematic cross-sectional view of the movable device 13 taken along the line XXVI-XXVI in FIG. 24. FIG. 27 is a schematic bottom view of an example of the movable device 13 according to the fourth embodiment of the present disclosure. FIG. 28 is a schematic cross-sectional view of the movable device 13 taken along the line XXVIII-XXVIII in FIG. 24.

In the movable device 13 according to the fourth embodiment of the present disclosure, the fifth drive portion 115a and the sixth drive portion 115b are disposed above the second SOI substrate 362 so that the displacement amount of the oscillation of the movable portion 101 about the first axis E1 as the rotation axis is increased. Accordingly, the scan range of the light beam incident on the mirror surface 14 in the direction along the second axis E2 is widened. The fifth drive portion 115a and the sixth drive portion 115b are examples of elastic support members.

The third drive portion 112a and the fourth drive portion 112b are formed in the silicon active layer 361c of the first SOI substrate 361. One end of the third drive portion 112a is coupled to the first torsion bar spring 111a. The other end of the third drive portion 112a is coupled to the fifth drive portion 115a via the inter-substrate coupling portion 160. One end of the fourth drive portion 112b is coupled to the second torsion bar spring 111b. The other end of the fourth drive portion 112b is coupled to the sixth drive portion 115b via the inter-substrate coupling portion 160. The other ends of the fifth drive portion 115a and the sixth drive portion 115b are coupled to the inner circumferential portion of the support portion 120.

The support portion 120 includes a silicon support layer 362a, a silicon oxide layer 362b, and a silicon active layer 362c of the second SOI substrate 362. The frame of the support portion 120 surrounds the movable portion 101, the third drive portion 112a, the fourth drive portion 112b, the fifth drive portion 115a, and the sixth drive portion 115b in a top view.

In the fourth embodiment of the present disclosure, since the driving force that oscillates the movable portion 101 about the first axis E1 is obtained from both the third drive portion 112a and the fifth drive portion 115a, a large displacement amount can be obtained. Further, the antiphase drive voltage is applied to the third drive portion 112a and the fifth drive portion 115a through separate wiring, displacements in both directions are obtained, as in the meander structure in driving the movable portion 101 with the second axis E2 as a rotation axis, and a large displacement is obtained.

The lower drive portion 131v is formed in the silicon active layer 362c of the second SOI substrate 362. The lower drive portion 131v has a meander structure in which multiple drive beams are coupled so as to be folded back. One end of each of the first lower drive beam 112v-1 and the second lower drive beam 112v-2 is coupled to the outer circumferential portion of the support portion 120. The other end of the first lower drive beam 112v-1 is coupled to the first upper drive beam 112u-1 via the inter-substrate coupling portion 160. The other end of the second lower drive beam 112v-2 is coupled to the second upper drive beam 112u-2 via the inter-substrate coupling portion 160.

The first upper drive beam 112u-1 and the second upper drive beam 112u-2 are formed in the silicon active layer 361c of the first SOI substrate 361, and have a meander structure in which multiple drive beams are coupled so as to be folded back.

One end of the first upper drive beam 112u-1 is coupled to the first lower drive beam 112v-1 via the inter-substrate coupling portion 160. The other end of the first upper drive beam 112u-1 is coupled to the inner circumferential portion of the fixed frame 140. In the inter-substrate coupling portion 160, electrical wiring is connected between the first SOI substrate 361 and the second SOI substrate 362 by the through-silicon via 162 in order to apply a voltage to the piezoelectric portion 202.

### Fifth Embodiment

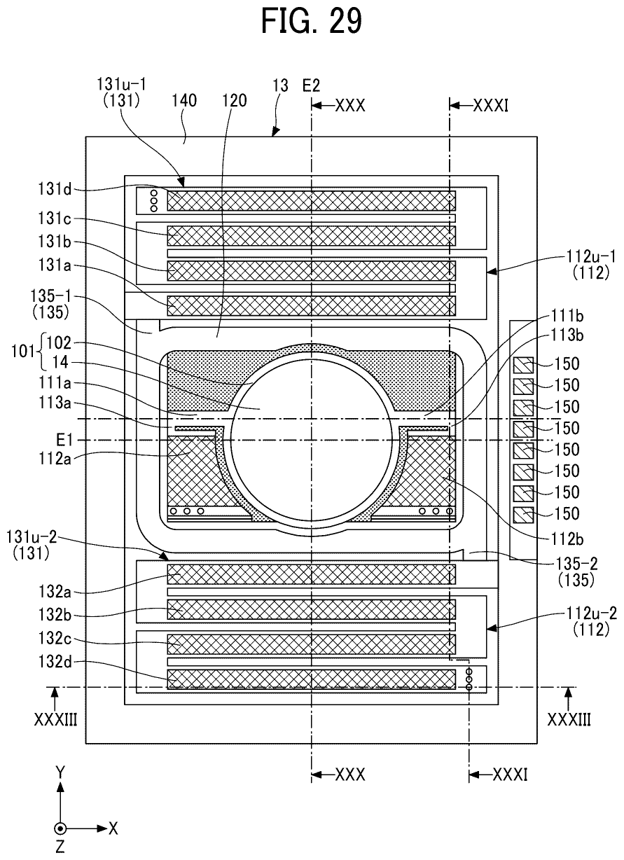

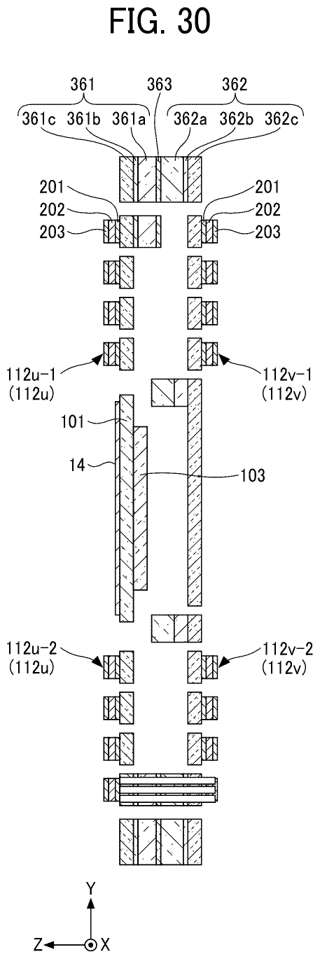

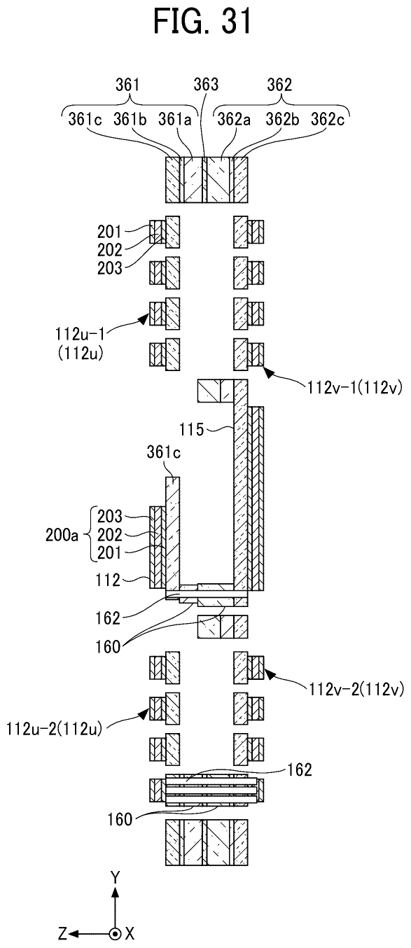

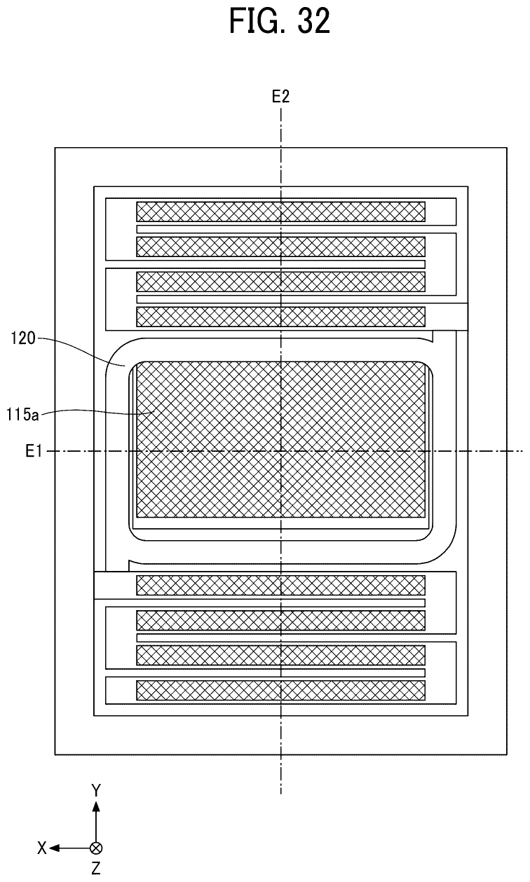

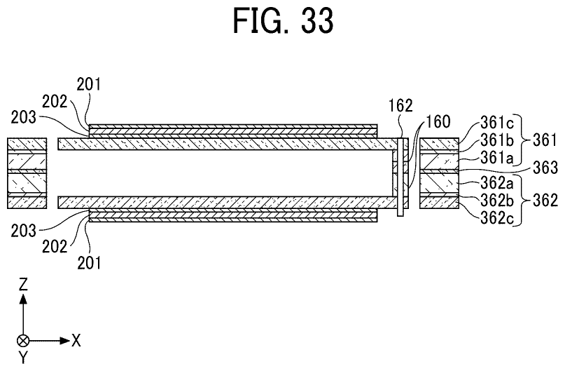

A movable device according to a fifth embodiment of the present disclosure will be described with reference to FIGS. 29 to 33. FIG. 29 is a schematic top view of an example of the movable device 13 according to the fifth embodiment of the present disclosure. FIG. 30 is a schematic cross-sectional view of the movable device 13 taken along the line XXX-XXX in FIG. 29. FIG. 31 is a schematic cross-sectional view of the movable device 13 taken along the line XXXI-XXXI in FIG. 29. FIG. 32 is a schematic bottom view of an example of the movable device 13 according to the fifth embodiment of the present disclosure. FIG. 33 is a schematic cross-sectional view of the movable device 13 taken along the line XXXIII-XXXIII in FIG. 29.

The movable device 13 according to the fifth embodiment of the present disclosure differs from the movable device 13 according to the first embodiment of the present disclosure in that the second SOI substrate 362 is turned upside down.

For example, the movable device 13 is formed by bonding two SOI substrates, i.e., a first SOI substrate 361 and a second SOI substrate 362, with a silicon oxide layer 363 therebetween. The first SOI substrate 361 includes a silicon support layer 361a, a silicon oxide layer 361b, and a silicon active layer 361c, and the second SOI substrate 362 includes a silicon support layer 362a, a silicon oxide layer 362b, and a silicon active layer 362c.

In the movable device 13 according to the fifth embodiment of the present disclosure, the silicon support layer 361a of the first SOI substrate 361 and the silicon support layer 362a of the second SOI substrate 362 are bonding surfaces. In other words, the second SOI substrate 362 is turned upside down.

In the movable device 13 according to the fifth embodiment of the present disclosure, the area of the fifth driving portion 115a can be increased by turning the second SOI substrate 362 upside down, and a larger amount of displacement of the movable portion 101 can be obtained. For example, the lower drive beam 112v is formed in a shape that avoids the rib 103 so that the fifth drive portion 115a does not interfere with the rib 103 on the back surface of the movable portion 101 when the lower drive beam 112v and the fifth drive portion 115a are driven in the oscillation of the movable portion 101 about the first axis E1 as the rotation axis. In the fifth embodiment of the present disclosure, the space in the Z-direction obtained due to the silicon support layer 362a of the second SOI substrate 362 can prevent interference with the rib 103 on the back surface of the movable portion 101. Accordingly, the area of the fifth drive portion 115a can be increased, and the displacement of the movable portion 101 in the oscillation about the first axis E1 as the rotation axis can be increased.

### Sixth Embodiment

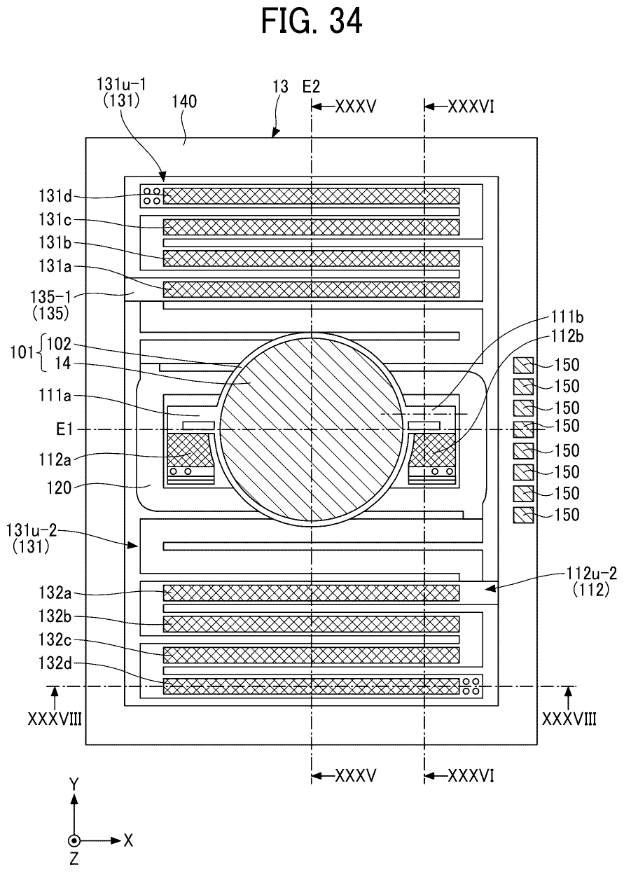

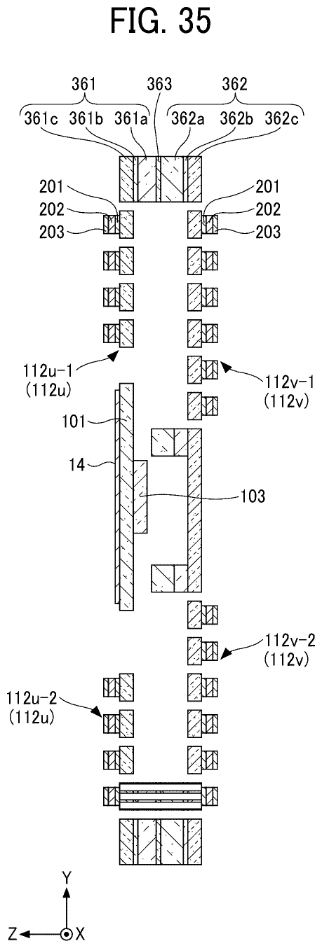

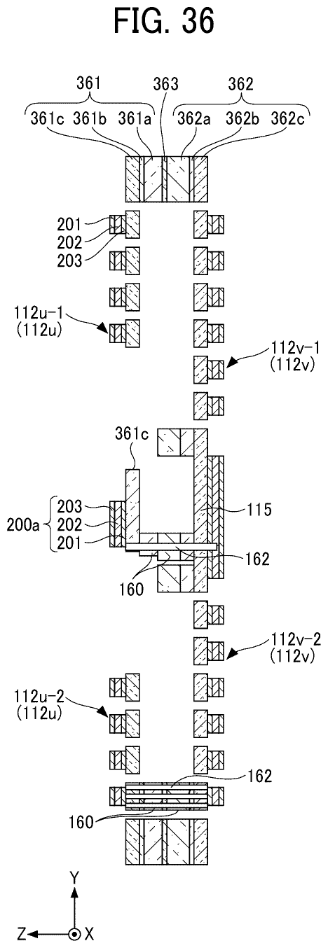

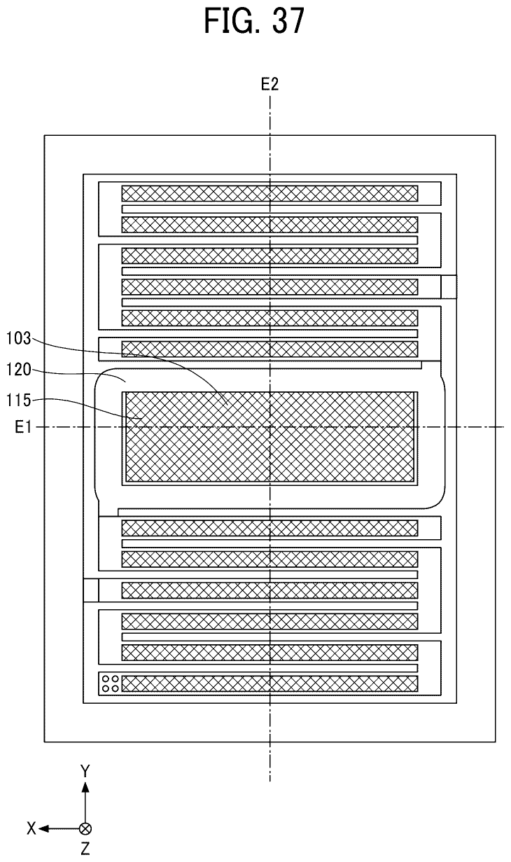

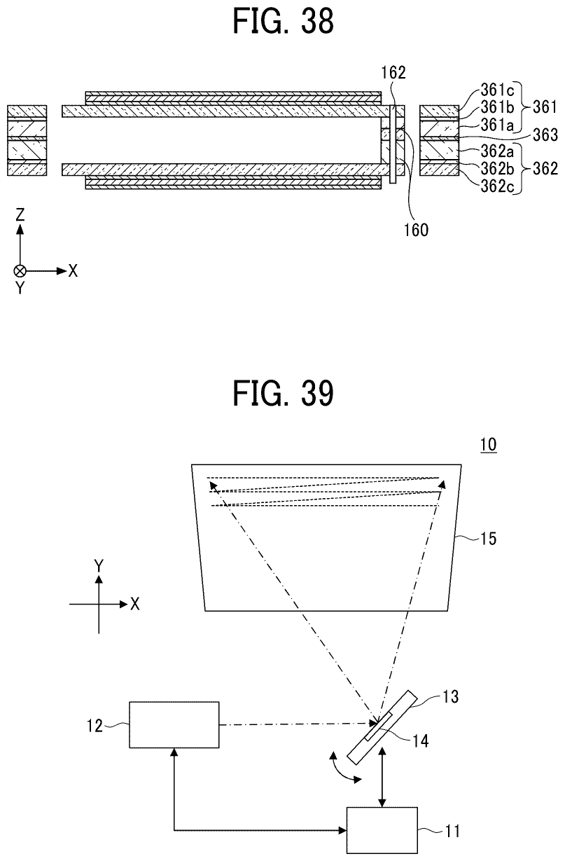

A movable device according to a sixth embodiment of the present disclosure will be described with reference to FIGS. 34 to 38. FIG. 34 is a schematic top view of an example of the movable device 13 according to the sixth embodiment of the present disclosure. FIG. 35 is a schematic cross-sectional view of the movable device 13 taken along the line XXXV-XXXV in FIG. 34. FIG. 36 is a schematic cross-sectional view of the movable device 13 taken along the line XXXVI-XXXVI in FIG. 34. FIG. 37 is a schematic bottom view of an example of the movable device 13 according to the sixth embodiment of the present disclosure. FIG. 38 is a schematic cross-sectional view of the movable device 13 taken along the line XXXVIII-XXXVIII in FIG. 34.

The movable device 13 according to the sixth embodiment of the present disclosure differs from the movable device 13 according to the first embodiment of the present disclosure in that the size of the movable portion 101 is larger than that of the structure in which the movable portion 101 oscillates about the first axis E1 as a rotation axis.

In the movable device 13 according to the sixth embodiment of the present disclosure, the movable portion 101 is formed to be one size larger than the structure in which the movable portion 101 oscillates about the first axis E1 as the rotation axis, and is larger than the support portion 120. Since the support portion 120 is formed of a thick silicon support layer, the size of the support portion 120 has a large influence on the moment of inertia. The support portion 120 is formed so as to be smaller than the size of the movable portion 101 so that the moment of inertia can be small.

In the movable device 13 according to the sixth embodiment of the present disclosure, the upper drive beam 112u includes four drive beams, and the lower drive beam 112v includes six drive beams. In other words, the number of drive beams in the upper drive beam 112u is smaller than the number of drive beams in the lower drive beam 112v. The number of drive beams in the upper drive beam 112u is smaller than the number of drive beams in the lower drive beam 112v so that the movable portion 101 can be larger. In other words, the main frame can be formed relatively smaller.

In the movable device 13 according to the sixth embodiment of the present disclosure, the rib 103 of the movable portion 101 and the support portion 120 are disposed so as not to overlap each other in the Z-direction. Accordingly, the mutual interference in the deformation in the Z-direction during operation can be prevented.

### Embodiment of Application

Embodiments of various applications to which the movable device 13 according to embodiments of the present disclosure is applied will be described below.

### Light Scan System

First, a light scan system 10 to which the movable device 13 according to an embodiment of the present disclosure is applied will be described in detail with reference to FIGS. 39 to 42. FIG. 39 is a schematic diagram illustrating an example of the light scan system 10. As illustrated in FIG. 39, the light scan system 10 deflects the light beam emitted from a light source device 12 by the mirror surface 14 of the movable device 13 under the control of a control device 11, and optically scans a scan surface 15 with the light beam.

The light scan system 10 includes the control device 11, the light source device 12, and the movable device 13 having the mirror surface 14.

The control device 11 is an electronic circuit unit including, for example, a central processing unit (CPU) and a field-programmable gate array (FPGA). The movable device 13 is, for example, a micro electromechanical systems (MEMS) device having a mirror surface 14 and can move the mirror surface 14. The light source device 12 is, for example, a laser device to emit a laser beam. The scan surface 15 is, for example, a screen.

The control device 11 generates a control command for the light source device 12 and the movable device 13 based on the obtained optical scan information, and outputs a drive signal to the light source device 12 and the movable device 13 based on the control command.

The light source device 12 irradiates an object with a light beam based on the input drive signal. The movable device 13 moves the mirror surface 14 in at least one of one-axial direction or two-axial directions based on the input drive signal.

Accordingly, for example, the mirror surface 14 of the movable device 13 is reciprocated in two-axial directions within a predetermined range by the control device 11 based on image information as an example of optical scan information so that the irradiation light beam from the light source device 12 that goes in the mirror surface 14 is deflected around a certain axis to perform optical scan. As a result, any image is projected onto the scan surface 15.

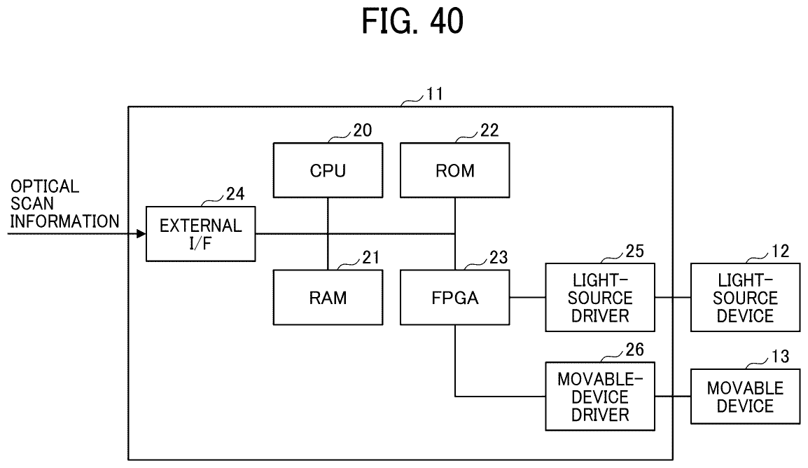

A hardware configuration of an example of the light scan system 10 will be described with reference to FIG. 40. FIG. 40 is a diagram illustrating a hardware configuration of a light scan system 10. As illustrated in FIG. 40, the light scan system 10 includes a control device 11, a light source device 12, and a movable device 13, which are electrically connected. The control device 11 includes a CPU 20, a random-access memory (RAM) 21, a read-only memory (ROM) 22, an FPGA 23, an external input and output (I/F) 24, a light source driver 25, and a movable device driver 26.

The CPU 20 is a computing device that reads programs and data from a storage device such as the ROM 22 to the RAM 21 and executes processing to implement the overall control and functions of the control device 11. The RAM 21 is a volatile storage device to temporarily hold programs and data. The ROM 22 is a nonvolatile storage device that can retain programs and data even when the power is turned off, and stores processing programs and data executed by the CPU 20 to control the functions of the light scan system 10. The FPGA 23 is a circuit that outputs control signals suitable for the light source driver 25 and the movable device driver 26 in accordance with the processing of the CPU 20.

The external I/F 24 is, for example, an interface with an external device or a network. Examples of the external device include a host device such as a personal computer (PC), and a storage device such as a universal serial bus (USB) memory, an SD card, a compact disk (CD), a digital versatile disk (DVD), a hard disk drive (HDD), or a solid-state drive (SSD). The network is, for example, a controller area network (CAN) for an automobile, a local area network (LAN), and the Internet. The external I/F 24 may enable connection or communication with the external device, and the external I/F 24 may be prepared for each external device.

The light source driver is an electric circuit that outputs a drive signal such as a drive voltage to the light source device 12 in accordance with an input control signal. The movable device driver 26 is an electric circuit that outputs a drive signal such as a drive voltage to the movable device 13 in accordance with an input control signal. In the control device 11, the CPU 20 acquires optical scan information from an external device or a network via the external I/F 24. Any configuration is acceptable as long as the CPU 20 can acquire the optical scan information, and the optical scan information may be stored in the ROM 22 or the FPGA 23 in the control device 11. Alternatively, for example, a storage device such as an SSD may be additionally disposed in the control device 11 and the optical scan information may be stored in the storage device.

The optical scan information is information indicating how the scan surface 15 is optically scanned, and for example, when an image is displayed by optical scan, the optical scan information is image data. In addition, for example, when optical writing is performed by optical scan, the optical scan information is writing data indicating a writing order and a writing position. Further, for example, when an object is recognized by optical scan, the optical scan information includes irradiation data indicating the irradiation timing and an irradiation range with a light beam for object recognition.

The control device 11 can implement a functional configuration described below by an instruction of the CPU 20 and the hardware configuration illustrated in FIG. 40.

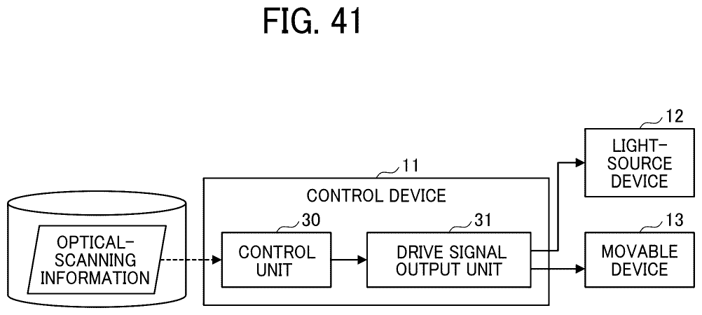

The functional configuration of the control device 11 of the light scan system 10 will be described with reference to FIG. 41. FIG. 41 is a functional block diagram illustrating an example of a control device of the light scan system. As illustrated in FIG. 41, the control device 11 includes a control unit 30 and a drive signal output unit 31 as functions.

The control unit 30 is implemented by, for example, the CPU 20 or the FPGA 23, obtains the optical scan information from an external device, converts the optical scan information into a control signal, and outputs the control signal to the drive signal output unit 31. For example, the control unit 30 obtains image data as optical scan information from, for example, an external device, generates a control signal from the image data by predetermined processing, and output the control signal to the drive signal output unit 31. The drive signal output unit 31 is implemented by the light source driver 25 and the movable device driver 26, and outputs a drive signal to the light source device 12 or the movable device 13 based on the input control signal.

The drive signal is a signal for controlling the drive of the light source device 12 or the movable device 13. For example, in the light source device 12, the drive voltage is used to control the irradiation timing and the irradiation intensity of the light source. In addition, for example, in the movable device 13, the drive voltage is a drive voltage for controlling the timing and the movable range of the mirror surface 14 of the movable device 13.

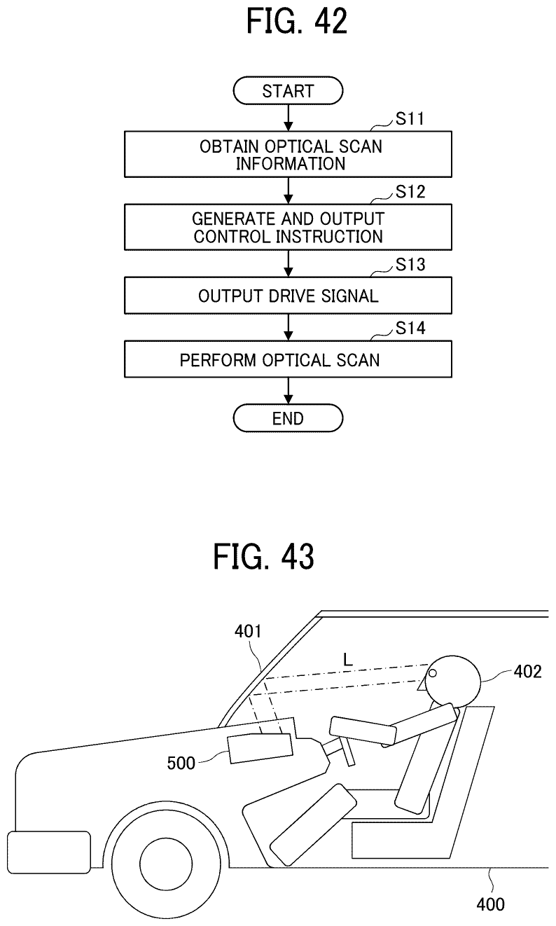

The process in which the light scan system 10 optically scans the scan surface 15 with a light beam will be described with reference to FIG. 42. FIG. 42 is a flowchart of an example of a process related to an optical scanner.

In step S11, the control unit 30 obtains optical scan information from an external device. In step S12, the control unit 30 generates a control signal from the obtained optical scan information and outputs the control signal to the drive signal output unit 31. In step S13, the drive signal output unit 31 outputs a drive signal to the light source device 12 and the movable device 13 based on the input control signal.

In step S14, the light source device 12 performs light irradiation based on the input drive signal. The movable device 13 moves the mirror surface 14 based on the input drive signal. The light source device 12 and the movable device 13 are driven so that the light beam is deflected in any direction, and optically scan is performed.

In the light scan system 10 described above, a single control device 11 includes a device and a function of controlling the light source device 12 and the movable device 13, but the device and the function may be disposed separately from the control device for the light source device and the control device for the movable device.

In the light scan system 10, the functions of the control unit 30 of the light source device 12 and the movable device 13 and the function of the drive signal output unit 31 are disposed in one control device 11, but these functions may be disposed separately. For example, a drive signal output device including the drive signal output unit 31 is disposed separately from the control device 11 including the control unit 30. The light scan system 10 described above may include an optical deflection system to perform light deflection by the movable device 13 having the mirror surface 14, and the single control device 11.

The light scan system 10 includes the movable device 13 that can obtain a large displacement amount while increasing the displacement stability. As a result, the light scan system 10 can scan a wide range with a light beam with high accuracy.

### Image Projection Apparatus

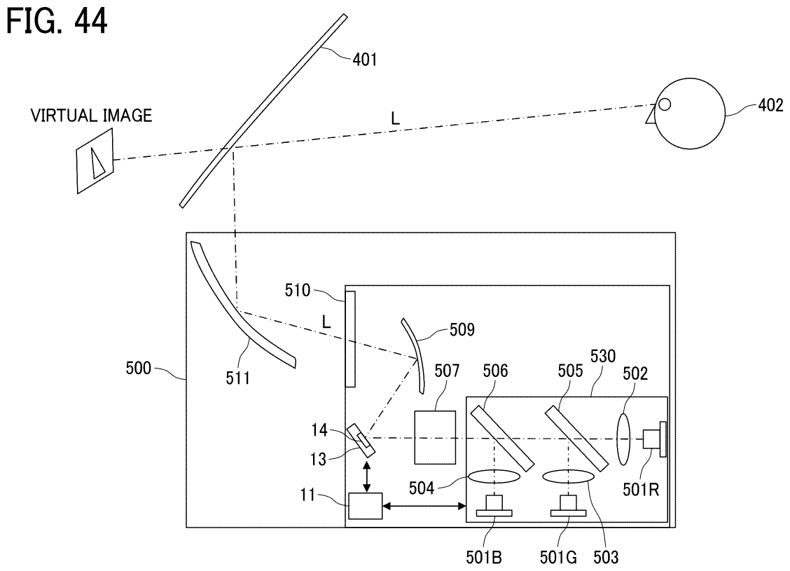

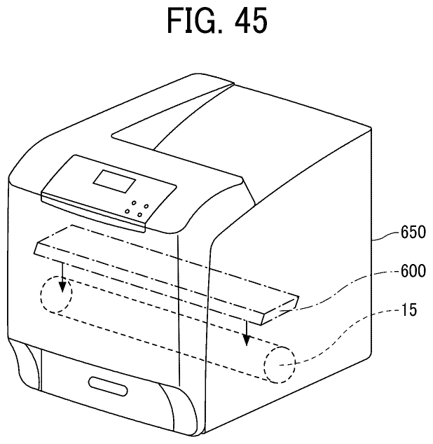

An image projection apparatus including the movable device according to the present embodiment will be described in detail with reference to FIGS. 43 and 44. FIG. 43 is a schematic view of an automobile 400 including a head-up display device 500 as an example of an image projection apparatus. FIG. 44 is a schematic diagram illustrating an example of a head-up display device 500.

The image projection apparatus is an apparatus that projects an image by optical scan, and is, for example, a head-up display device.

As illustrated in FIG. 43, the head-up display device 500 is installed, for example, near a windshield (e.g., a front window 401) of an automobile 400. The projection light beam L emitted from the head-up display device 500 is reflected by the front window 401 and directed to an observer (e.g., a driver 402) that is a user. Accordingly, the driver 402 can visually recognize the image projected by the head-up display device 500 as a virtual image. A combiner may be disposed on an inner wall surface of the windshield, and the user may visually recognize a virtual image by the projected light beam reflected by the combiner.

As illustrated in FIG. 44, in the head-up display device 500, a red laser light source 501R emits a red laser beam, a green laser light source 501G emits a green laser beam, and a blue laser light source 501B emits a blue laser beam. These three emitted laser beams pass through an incident optical system, and are deflected by a movable device 13 including a mirror surface 14. The incident optical system includes a collimator lens 502, a collimator lens 503, and a collimator lens 504, which are disposed for the red laser beam, the green laser beam, and the blue laser beam, respectively, two dichroic mirrors 505 and 506, and a light amount adjusting unit 507. The deflected laser beams are projected onto a screen through a projection optical system including a free-form surface mirror 509, an intermediate screen 510, and a projection mirror 511. In the head-up display device 500, the red laser light source 501R, the green laser light source 501G, and the blue laser light source 501B, the collimator lens 502, the collimator lens 503, the collimator lens 504, the dichroic mirror 505, and the dichroic mirror 506 are formed as a light source unit 530 by an optical housing.

The head-up display device 500 described above projects an intermediate image displayed on the intermediate screen 510 on the front window 401 of the automobile 400 so that the driver 402 can be visually recognized the intermediate image as a virtual image.

The red laser beam emitted from the red laser light source 501R, the green laser beam emitted from the green laser light source 501G, and the blue laser beam emitted from the blue laser light source 501B are collimated by the collimator lens 502, the collimator lens 503, and the collimator lens 504, respectively, as substantially parallel laser beams, and are combined by the two dichroic mirrors 505 and 506. The amount of the combined laser beam is adjusted by the light amount adjusting unit 507, and the movable device 13 including the mirror surface 14 two-dimensionally scans the free-form surface mirror 509 with the laser beam. The projection light beam L with which the movable device 13 two-dimensionally scans the free-form surface mirror 509 is reflected by the free-form surface mirror 509 is corrected in distortion, and is condensed on the intermediate screen 510 to display an intermediate image. The intermediate screen 510 includes a microlens array in which microlenses are two-dimensionally arranged, and enlarges the projection light beam L incident on the intermediate screen 510 at each microlens.

The movable device 13 reciprocates the mirror surface 14 in two-axial directions and two-dimensionally scans the free-form surface mirror 509 with the projection light beam. The control of the movable device 13 is performed in synchronism with the timing of light emission of the red laser light source 501R, the green laser light source 501G, and the blue laser light source 501B.

As described above, the head-up display device 500 has been described as an example of the image projection apparatus, but the image projection apparatus may be any device that projects an image by performing optical scan with the movable device 13 including the mirror surface 14. For example, the image projection apparatus can be applied to a projector that is placed on a desk and projects an image on a display screen, and a head-mounted display device that projects an image to a reflective-and-transmissive screen included in a mounting member mounted on an observer's head or projects an image to an eyeball as a screen.

The image projection apparatus may be included in not only a vehicle and a mounting member but also, for example, a moving body such as an aircraft, a ship, and a mobile robot, or a non-moving body such as a work robot that operates a drive object such as a manipulator without moving from the site.

The head-up display device 500 is an example of a head-up display. The automobile 400 is an example of a vehicle.

Since the head-up display device 500 includes the movable device 13 that can obtain a large displacement amount while increasing the displacement stability, a large screen image with high image quality can be displayed.

### Optical Writing Apparatus

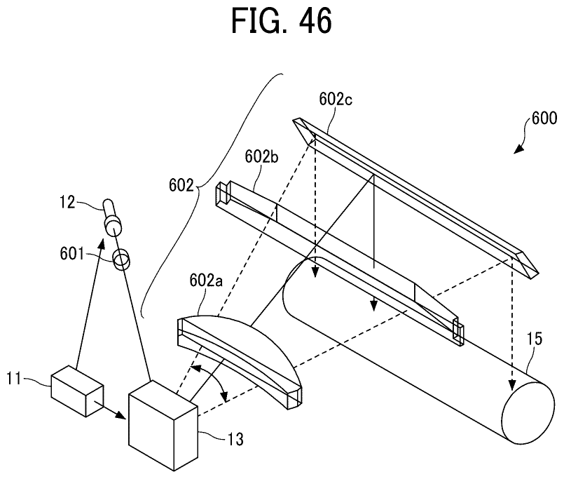

An optical writing apparatus to which the movable device 13 of the present embodiment is applied will be described in detail with reference to FIGS. 45 and 46.

FIG. 45 is a schematic diagram illustrating an example of an image forming apparatus including an optical writing apparatus 600. FIG. 46 is a schematic diagram illustrating an example of the optical writing apparatus 600.

As illustrated in FIG. 45, the optical writing apparatus 600 is used as a unit of an image forming apparatus such as a laser printer 650 having a printer function using a laser beam. In the image forming apparatus, the optical writing apparatus 600 optically scans a photoconductive drum that serves as a scan surface 15 with one or multiple laser beams, to perform optical writing to the photoconductive drum.

As illustrated in FIG. 46, in the optical writing apparatus 600, a laser beam from a light source device 12 such as a laser element passes through an imaging optical system 601 such as a collimator lens, and is deflected in one-axial direction or two-axial directions by a movable device 13 including a mirror surface 14. The laser beam deflected by the movable device 13 passes through the scanning optical system 602 including a first lens 602a, a second lens 602b, and a reflecting mirror portion 602c, and the optical writing apparatus 600 irradiates the scan surface 15 (e.g., photoconductive drum or photosensitive paper) with the laser beam to perform optical writing. The scanning optical system 602 forms an image of a light beam in a spot shape on the scan surface 15. The light source device 12 and the movable device 13 including the mirror surface 14 are driven based on the control of the control device 11.

As described above, the optical writing apparatus 600 can be used as a member of an image forming apparatus having a printer function by a laser beam. Further, the optical writing apparatus 600 can change the scanning optical system to perform optical scan not only in one-axial direction but also two-axial directions, and thus can be used as a unit of the image forming apparatus such as a laser label apparatus that deflects the laser beam to a thermal medium to print by heating.

Since the movable device 13 including the mirror surface 14 applied to the optical writing apparatus has a smaller power consumption for driving than a rotary polygon mirror using a polygon mirror, and the movable device 13 has an advantage in saving power of the optical writing apparatus. In addition, since the wind noise generated when the movable device 13 is vibrated is smaller than the wind noise of the rotary polygon mirror, it is advantageous for increasing the quietness of the optical writing apparatus. The optical writing apparatus requires a much smaller installation space than the rotary polygon mirror, and the movable device 13 generates a small amount of heat, so that the optical writing apparatus can be easily reduced in size. As a result, the image forming apparatus has an advantage in reducing in size.

Since the optical writing apparatus 600 includes the movable device 13 that can obtain a large displacement amount while increasing the displacement stability, an image with high image quality can be formed on a large region of a recording medium.

### Object Recognition Apparatus

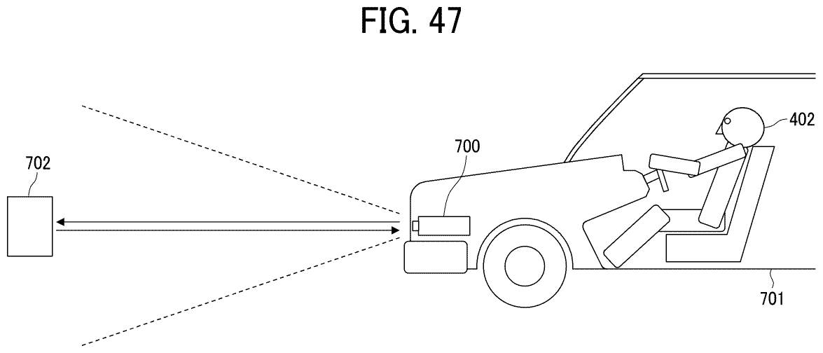

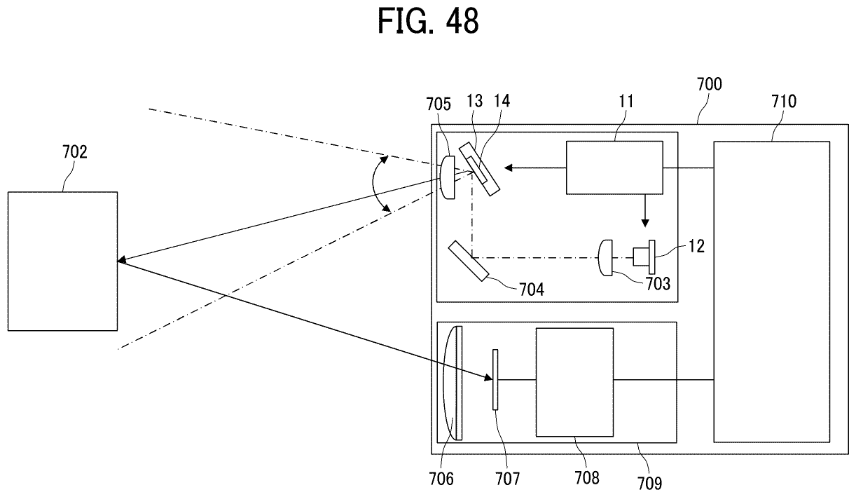

An object recognition apparatus to which the movable device of the present embodiment is applied will be described in detail with reference to FIGS. 47 and 48.

FIG. 47 is a schematic diagram illustrating an automobile in which a laser imaging detection and ranging (LiDAR) apparatus that is an example of an object recognition apparatus is mounted. In the schematic diagram, the LiDAR apparatus is mounted on a lighting unit including a headlight of the automobile. FIG. 48 is a schematic diagram illustrating an example of a LiDAR apparatus.

The object recognition apparatus is an apparatus that recognizes an object in a target direction, and is, for example, a LiDAR apparatus. As illustrated in FIG. 47, the LiDAR apparatus 700 is mounted on, for example, an automobile 701, and scans a region with a light beam in a predetermined direction, and recognizes the object 702 in the region by receiving the reflected light beam from the object 702.

As illustrated in FIG. 48, the movable device 13 includes an incident optical system including a collimate lens 703 that is an optical system to form a divergent light beam into a substantially parallel light beam, and a plane mirror 704. The movable device 13 including the mirror surface 14 scans an object with the laser beam that is emitted from the light source device 12 and passes through the incident optical system in a one-axial direction or two-axial directions. The substantially parallel light deflected by the movable device 13 reaches the object 702 in front of the LiDAR apparatus 700 via a projection lens 705 that is a projection optical system. The control device 11 drives the light source device 12 and the movable device 13. The light detector 709 detects the reflected light beam reflected by the object 702. In other words, the reflected light beam passes through a condenser lens 706 that is an optical system for receiving and detecting the incident light beam, and is received by an image sensor 707. The image sensor 707 outputs a detected signal to a signal processing circuit 708. The signal processing circuit 708 performs predetermined processing such as binarization or noise processing on the received detection signal, and outputs the result to a distance measurement circuit 710.

The distance measurement circuit 710 determines the presence or absence of the object 702 according to a time difference between a timing at which the light source device 12 emits the laser beam and a timing at which the light detector 709 receives the laser beam, or a phase difference for each pixel of the image sensor 707 that receives the laser beam, and calculates distance information with respect to the object 702.

Since the movable device 13 including the mirror surface 14 is less likely to be damaged as compared with a polygon mirror and is smaller in size, a smaller LiDAR apparatus having higher durability can be provided. When the LiDAR apparatus is attached to, for example, a vehicle, an aircraft, a ship, or a robot, the presence or absence of an obstacle or an object can be determined or the distance to the obstacle or the object can be recognized by performing optical scan within a predetermined range.

In the object recognition apparatus described above, the LiDAR apparatus 700 is described as an example. However, the object recognition apparatus is not limited to the embodiment described above as long as the object recognition apparatus performs optical scan by the movable device 13 including the mirror surface 14 under control of the control device 11 and receives the reflection light beam by the light detector to recognize the object 702.

The object recognition apparatus described above can be applied to, for example, a biometric authentication apparatus that calculates object information such as a shape from the distance information obtained by scanning a hand or a face and recognizes the object by referring the record, a security sensor that recognizes an intruder by optically scanning the object region, or a unit of the three-dimensional scanner that outputs three-dimensional data.

Since the object recognition apparatus includes the movable device 13 that can obtain a large displacement amount while increasing the displacement stability, the object recognition apparatus can recognize an object in a wide range with high accuracy.

### Laser Headlamp

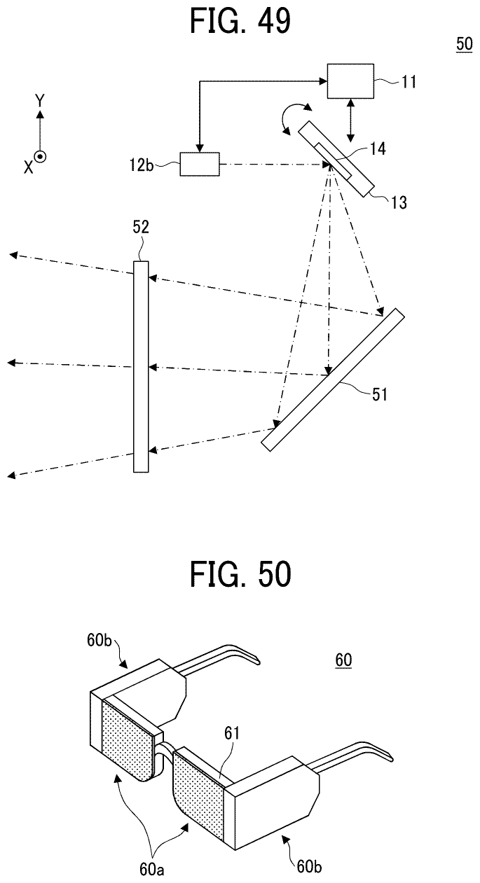

A laser headlamp 50 in which the movable device of the present embodiment is applied to a headlight of an automobile will be described with reference to FIG. 49. FIG. 49 is a schematic diagram illustrating an example of a configuration of the laser headlamp 50.

The laser headlamp 50 includes a control device 11, a light source device 12b, a movable device 13 including a mirror surface 14, a mirror 51, and a transparent plate 52.

The light source device 12b is a light source that emits a blue laser beam. The light beam emitted from the light source device 12b goes in the movable device 13 and is reflected by the mirror surface 14. The movable device 13 moves the mirror surface in the X- and Y-directions based on the signal from the control device 11, and two-dimensionally scans an object with the blue laser beam from the light source device 12b in the X- and Y-directions.

The scan light beam by the movable device 13 is reflected by the mirror 51 and goes in the transparent plate 52. The front surface or the back surface of the transparent plate 52 is coated with a yellow fluorescent material. The blue laser beam from the mirror 51 changes to white in the legalized range of the color of the headlight when passing through the yellow phosphor coating of the transparent plate 52. Thus, the area ahead of the automobile is illuminated with the white light beam from the transparent plate 52.

The scan light beam by the movable device 13 is scattered in a predetermined manner when passing through the fluorescent material of the transparent plate 52. Accordingly, the glare of the illumination object ahead of the automobile is reduced.

When the movable device 13 is applied to a headlight of an automobile, the colors of the light source device 12b and the fluorescent material are not limited to blue and yellow, respectively. For example, the light source device 12b may be a near-ultraviolet light source, and the transparent plate 52 may be coated with a mixture of uniformly mixed phosphors of blue, green, and red, which are the three primary colors of light. In this case, the light beam passing through the transparent plate 52 can be converted into white light, and the area ahead of the automobile can be illuminated with white light beam.

Since the laser headlamp 50 includes the movable device 13 that can obtain a large displacement amount while increasing the displacement stability, the laser headlamp can irradiate a wide region with a laser beam with high accuracy.

### Head-Mounted Display

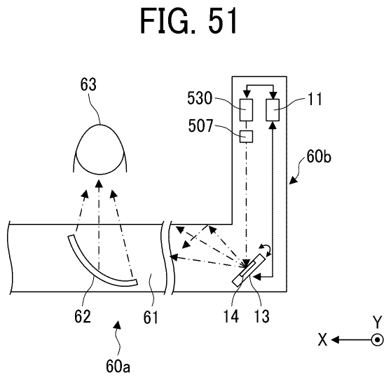

A head-mounted display (HMD) 60 to which the movable device of the present embodiment is applied will be described with reference to FIGS. 50 and 51. The HMD 60 is a head-mounted display that can be mounted on the human head, and has a shape of, for example, glasses.

FIG. 50 is a perspective view of an external appearance of the HMD 60. In FIG. 50, the HMD 60 includes fronts 60a symmetrically disposed in a pair on the left and right sides and temples 60b. The fronts 60a can be formed by, for example, light guide plates 61, and an optical system and a control device can be built in the temples 60b.

FIG. 51 is a diagram illustrating a partial configuration of the HMD 60. Although FIG. 51 illustrates the partial configuration for the left eye, the HMD 60 has the same configuration for the right eye.

The HMD 60 includes a control device 11, a light source unit 530, a light amount adjusting unit 507, a movable device 13 including a mirror surface 14, a light guide plate 61, and a half mirror 62.

As described above, the light source unit 530 includes the red laser light source 501R, the green laser light source 501G, the blue laser light source 501B, the collimator lens 502, the collimator lens 503, the collimator lens 504, the dichroic mirror 505, and the dichroic mirror 506 in an optical housing as a unit. In the light source unit 530, the red laser beam from the red laser light source 501R, the green laser beam from the green laser light source 501G, and the blue laser beam from the blue laser light source 501B are combined by the dichroic mirror 505 and the dichroic mirror 506. The light source unit 530 emits the combined parallel light beam.

The light beam from the light source unit 530 is adjusted by the light amount adjusting unit 507 in its light amount and goes in the movable device 13. The movable device 13 moves the mirror surface 14 in the X- and Y-directions based on the signal from the control device 11, and two-dimensionally scans an object with the laser beam from the light source unit 530. The control of the movable device 13 is performed in synchronism with the timing of light emission of the red laser light source 501R, the green laser light source 501G, and the blue laser light source 501B, and a color image is formed by optical scan.

The scan light beam by the movable device 13 goes in the light guide plate 61. The light guide plate 61 guides the scan light beam to the half mirror 62 while reflecting the scan light beam on the inner wall surfaces. The light guide plate 61 is made of a resin having a transparency with respect to the wavelength of the scan light beam.

The half mirror 62 reflects the light beam from the light guide plate 61 to the back surface side of the HMD 60 and emits the light beam in the direction of the eye of a wearer 63 of the HMD 60. The half mirror 62 has, for example, a free-form surface shape. The image by the scan light beam is reflected by the half mirror 62, and is imaged on the retina of the wearer 63. Alternatively, the image is formed on the retina of the wearer 63 by reflection at the half mirror 62 and the lens effect of the lens of the eyeball. The spatial distortion of the image is corrected by the reflection at the half mirror 62. The wearer 63 can observe the image formed with the light beam scanned in the X- and Y-directions.

Since the half mirror 62 is used, the wearer 63 observes a superimposed image of an image of a light beam from the outside and an image by scan light beam. A mirror may be used instead of the half mirror 62 so that the light beam from the outside is eliminated, and only an image by the scan light beam can be observed.

Since the HMD 60 includes the movable device 13 that can obtain a large displacement amount while increasing the displacement stability, the HMD 60 can display a large screen image with high image quality.

Tilt-Position Detection Apparatus of Eyeball (Position Detection Apparatus of Pupil or Cornea)

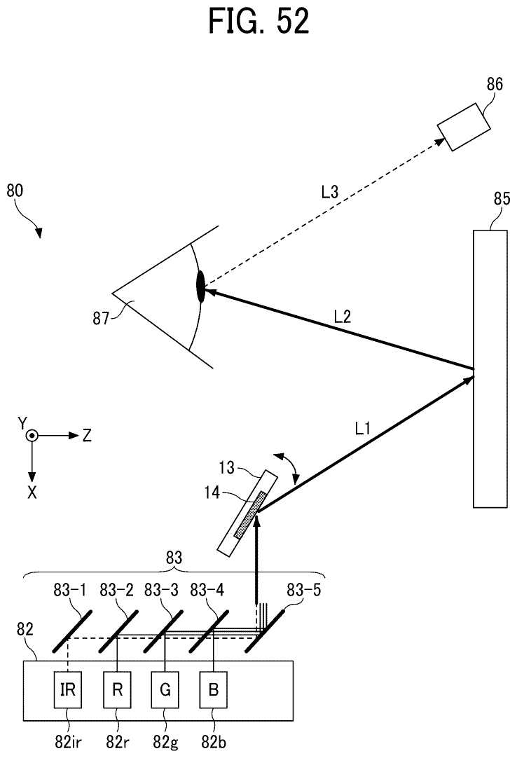

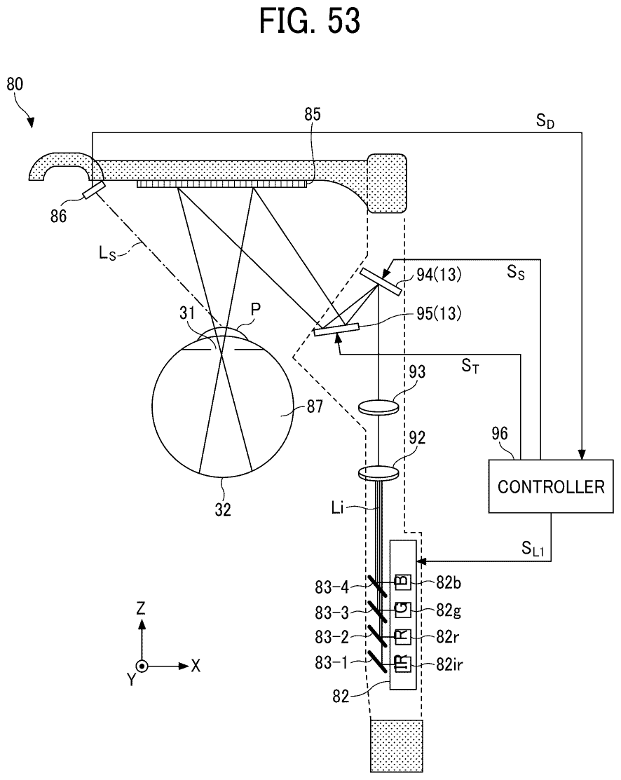

A tilt-position detection apparatus of an eyeball that includes the movable device 13 will be below. The tilt-position detection apparatus for the eyeball is a pupil-or-cornea position detection apparatus 80. FIG. 52 is a first schematic block diagram illustrating an example of a pupil-or-cornea position detection apparatus 80. FIG. 53 is a second schematic block diagram illustrating an example of the pupil-or-cornea position detection apparatus 80.

The “tilt-position of the eyeball” in the present embodiment is the position of the pupil-or-cornea of the eyeball or the direction of the user's line of sight. In the following description, the “tilt-position of the eyeball” is the position of the pupil or the cornea, and the “tilt-position detection apparatus of the eyeball” is the “pupil-or-cornea position detection apparatus.” The pupil-or-cornea position detection apparatus described below is the same as a line-of-sight direction tracking apparatus (eye tracking apparatus) that detects or tracks the direction of the user's line of sight continuously or at intervals of time.

The pupil-or-cornea position detection apparatus 80 illustrated in FIG. 52 includes a light source 82, a first light deflection part 83, a movable device 13, a second light deflection part 85, and a light receiving unit 86.

The light source 82 includes, for example, a red laser light source 82r to emit a red laser beam, a green laser light source 82g to emit a green laser beam, a blue laser light source 82b to a blue laser light beam, and an infrared laser light source 82ir to emit an infrared laser beam. The red laser light sources 82r, the green laser light source 82g, and the blue laser light source 82b may be any one or a combination of two. The red laser light sources 82r, the green laser light source 82g, and the blue laser light source 82b emit laser beams to form an image by the movable device 13.

The infrared laser light source 82ir emits a light beam to detect the position of the pupil or the cornea. The light beam for detecting the position of the pupil or the cornea is not limited to an infrared light beam, and may be a visible light beam. The light beam for detecting the position of the pupil or the cornea is preferably an invisible light beam from the viewpoint of increasing the visibility of a drawn image.

The first light deflection part 83 is, for example, a dichroic mirror, and deflects the light beam emitted from the light source 82 toward the mirror surface 14 of the movable device 13 while combining the light beams. The pupil-or-cornea position detection apparatus 80 may include multiple first light deflection parts 83-1, 83-2, 83-3, 83-4, and 83-5, in accordance with the number of the laser light sources (i.e., the red laser light sources 82r, the green laser light source 82g, the blue laser light source 82b, and the infrared laser light source 82ir). The first light deflection part 83 includes multiple first light deflection parts 83-1, 83-2, 83-3, 83-4, and 83-5. The multiple first light deflection parts 83-1, 83-2, 83-3, 83-4, and 83-5 deflect the light beams while combining the light beams.

The movable device 13 includes a mirror surface 14 and scans the second light deflection part 85 with the light beam deflected by the first light deflection part 83 in two-dimensional directions. At this time, the movable device 13 scans the second light deflection part 85 with the light beam deflected by the first light deflection part 83 using, for example, raster scan to form an image. The movable device 13 can scan the second light deflection part 85 with the light beam deflected by the first light deflecting part 83 by spiral scan.

The second light deflection part 85 is, for example, a holographic optical element, and deflects the light beam L1 with which the movable device 13 scanned toward the eyeball 87 of the user. At least a portion of the light beam L2 deflected by the second light deflection part 85 goes in the eyeball 87 of the user as display image light beam. The second light deflection part 85 may include multiple light deflection members. For example, multiple light deflection parts that reflect specific light beams among the light beams emitted from the light source 82 may be used, and the mirror surface may be different for each light beams emitted from the light source 82. As a specific example, a structure in which a light deflection part that reflects light beams emitted from the red laser light source 82r, the green laser light source 82g, and the blue laser light source 82b and a light deflection member for reflecting the light beam emitted from the infrared laser light source 82ir are laminated in order of proximity to the eyeball 87 can be used.

The light receiving unit 86 receives the light beam L3 reflected by the eyeball 87 of the user among the light beam L2 deflected by the second light deflection part 85, and outputs a detection signal SD corresponding to the received light beam. The light receiving unit 86 is an image sensor that can detect, for example, an infrared light beam. The light receiving unit 86 may include multiple light receiving units and be disposed at positions that can receive the light beam L3 reflected by the eyeball 87 of the user. The light beam received by the light receiving unit 86 changes in intensity depending on the change in position of the eyeball (e.g., pupil or cornea), that is, the change in the direction of the line of sight. Thus, the pupil-or-cornea position detection apparatus 80 of the pupil or the cornea in the present embodiment detects or estimates the position of the pupil or the cornea based on the intensity of the light beam received by the light receiving unit 86. The light receiving unit 86 may be configured to image the eyeball 87 irradiated with the light beam L2 deflected by the second light deflection part 85. In this case, the pupil-or-cornea position detection apparatus 80 detects or estimates the tilt-position of the eyeball 87 based on the position of the pupil or cornea included in the captured image (i.e., detection signal SD) and the position at which the light beam L2 deflected by the second light deflection part 85 is reflected in the eyeball 87.

As described above, the pupil-or-cornea position detection apparatus 80 according to the present embodiment can detect the position of the pupil or cornea while forming an image by the movable device 13. Further, since the movable device 13 has a configuration that can perform optical scan more efficiently, image formation and detection of the position of the pupil or cornea can be implemented with lower power. Further, the movable device 13 can obtain the above-described effect without changing the area necessary for mounting the pupil-or-cornea position detection apparatus 80 as compared with the configuration in the related art. Accordingly, a configuration in which the size of the pupil-or-cornea position detection apparatus 80 is not increased can be implemented.

The pupil-or-cornea position detection apparatus 80 can be mounted on a head-mounted display as, for example, an eye tracking apparatus, and can detect or track the direction of the user's line of sight. In this case, for example, the resolution of an image displayed in a region near the direction of the user's line of sight in other regions is reduced (i.e., foveal rendering) so that the image processing can be speeded up as compared with the case where a high-resolution image is displayed in the entire region.

As described above, preferable embodiments have been described in detail. However, embodiments according to the present disclosure are not limited to the embodiments described above, and various modifications and substitutions can be made to the above-described embodiments of the present disclosure without departing from the scope of the claims.

All the numerals such as ordinal numbers and numbers and reference symbols used in the description of the embodiments are illustrative for specifically describing the technique of the present invention, and the present invention is not limited to the illustrated numerals. In addition, a coupling relation between the components is an example for specifically describing the technology of the present disclosure, and a connection relation for implementing a function of the present disclosure is not limited thereto.

Aspects of the present disclosure are as follows, for example.

### First Aspect

A movable device includes a movable portion, a drive beam whose one end is directly or indirectly coupled to the movable portion, and a fixed frame to which another end of the drive beam is coupled. The drive beam includes multiple drive beams each including a drive portion. Each of the multiple drive beams includes an upper drive beam and a lower drive beam disposed in a normal direction of the fixed frame so as to be separated from the upper drive beam.

### Second Aspect

In the movable device according to the first aspect, the upper drive beam overlaps the lower drive beam as viewed from the normal direction of the fixed frame.

### Third Aspect

In the movable device according to the first or second aspect, the upper drive beam and the lower drive beam are different in number.

### Fourth Aspect

In the movable device according to any one of the first to third aspects, the upper drive beam is coupled to the lower drive beam by an adhesive.

### Fifth Aspect

In the movable device according to any one of the first to fourth aspects, the upper drive beam is driven by an antiphase drive voltage having a phase opposite to a phase of the drive voltage for driving the lower drive beam.

### Sixth Aspect

The movable device according to any one of the first to fifth aspects further includes an elastic support member disposed between the movable portion and one of the upper drive beam and the lower drive beam. The movable portion is resonantly driven.

### Seventh Aspect

In the movable device according to any one of the first to sixth aspects, the movable portion is arranged so as to be spaced from either the upper drive beam or the lower drive beam in a normal direction of the fixed frame.

### Eighth Aspect

In the movable device according to any one of the first to seventh aspects, the upper drive beam is electrically connected to the lower drive beam by wire bonding.

### Ninth Aspect

In the movable device according to any one of the first to seventh aspects, the upper drive beam is electrically connected to the lower drive beam via a through-silicon via.

### Tenth Aspect

An image projection apparatus includes the movable device according to any one of the first to ninth aspects.

### Eleventh Aspect

A head-up display includes the movable device according to any one of the first to ninth aspects.

### Twelfth Aspect

A laser headlamp includes the movable device according to any one of the first to ninth aspects.

### Thirteenth Aspect

A head-mounted display includes the movable device according to any one of the first to ninth aspects.

### Fourteenth Aspect

An object recognition apparatus includes the movable device according to any one of the first to ninth aspects.

### Fifteenth Aspect

A moving body includes at least one of the head-up display according to the eleventh aspect, the laser headlamp according to the twelfth aspect, or the object recognition apparatus according to the fourteenth aspect.

The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), and/or combinations thereof which are configured or programmed, using one or more programs stored in one or more memories, to perform the disclosed functionality. Processors are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality.

1. A movable device comprising:
a fixed frame;
a movable portion;
multiple drive beams to drive the movable portion, each of the multiple drive beams having:
an end directly or indirectly coupled to the movable portion; and
another end coupled to the fixed frame, and
each of the multiple drive beams including:
an upper drive beam; and
a lower drive beam separated from the upper drive beam in a normal direction of the fixed frame.

2. The movable device according to claim 1,
wherein the upper drive beam overlaps the lower drive beam in the normal direction of the fixed frame.

3. The movable device according to claim 1,
wherein the multiple drive beams include:
multiple upper drive beams including a first number of the upper drive beam; and
multiple lower drive beams including a second number different from the first number of the lower drive beam.

4. The movable device according to claim 1,
wherein the upper drive beam is coupled to the lower drive beam with an adhesive.

5. The movable device according to claim 1,
wherein the upper drive beam is driven by a first drive voltage; and
the lower drive beam is driven by a second drive voltage antiphase to the first drive voltage.

6. The movable device according to claim 1, further comprising:
an elastic support portion disposed between the movable portion and one of the upper drive beam or the lower drive beam,
wherein the movable portion is resonantly driven by one of the upper drive beam or the lower drive beam via the elastic support portion.

7. The movable device according to claim 1,
wherein the movable portion is separated from one of the upper drive beam or the lower drive beam in the normal direction of the fixed frame.

8. The movable device according to claim 1, further comprising:
a wire bonding electrically connecting the upper drive beam and the lower drive beam.

9. The movable device according to claim 1, further comprising:
a through-silicon via electrically connecting the upper drive beam and the lower drive beam.

10. An image projection apparatus comprising:
the movable device according to claim 1.

11. A head-up display comprising:
the movable device according to claim 1.

12. A laser headlamp comprising:
the movable device according to claim 1.

13. A head-mounted display comprising:
the movable device according to claim 1.

14. An object recognition apparatus comprising:
the movable device according to claim 1.

15. A moving body comprising:
the head-up display according to claim 11.

16. A moving body comprising:
the laser headlamp according to claim 12.

17. A moving body comprising:
the object recognition apparatus according to claim 14.

18. The movable device according to claim 1,
wherein the movable portion is in the fixed frame, and
each of the multiple drive beams is between the movable portion and the fixed frame in a direction orthogonal to the normal direction.
